(19) United States
(12) Patent Application Publication
(10) Pub. No.: US 2025/0212418 A1
(43) Pub. Date: Jun. 26, 2025

(54) SEMICONDUCOTOR DEVICE AND ELECTRONIC SYSTEM INCLUDING THE SAME

(71) Applicant: Samsung Electronics Co., Ltd., Suwon-si (KR)

(72) Inventors: Sangwoo Han, Suwon-si (KR); Moonkang Choi, Suwon-si (KR); JONGHO WOO, Suwon-si (KR); Seung Min Lee, Suwon-si (KR)

(21) Appl. No.: 18/991,929

(22) Filed: Dec. 23, 2024

(30) Foreign Application Priority Data
Dec. 22, 2023 (KR) 10-2023-0190303

(51) Int. Cl. H10B 51/30; H10B 51/10; H10B 51/40

(52) U.S. Cl. CPC H10B 51/30; H10B 51/10; H10B 51/40

(57) ABSTRACT

A semiconductor device includes a stacking structure disposed on a substrate and including a plurality of gate electrodes, a first channel structure penetrating the gate electrodes and including a first channel layer and a first ferroelectric layer including a vertical portion disposed between the first channel layer and a side surface of the stacking structure and a horizontal portion disposed on an upper surface of the stacking structure, a contact pad connected to the first channel structure, and a second channel structure connected to the contact pad. The contact pad includes a first portion contacting an upper surface of the first channel layer, a second portion penetrating the horizontal portion of the first ferroelectric layer and contacting an exterior surface of the first channel layer, and a third portion protruding from a bottom surface of the second portion and contacting the exterior surface of the first channel layer.

### CROSS-REFERENCE TO RELATED APPLICATION

This application claims priority to and the benefit of Korean Patent Application No. 10-2023-0190303 filed in the Korean Intellectual Property Office on Dec. 22, 2023, the entire contents of which are herein incorporated by reference.

### BACKGROUND

### 1. Field

The present disclosure relates to a semiconductor device and an electronic system including the same.

### 2. Description of the Related Art

A semiconductor is a material that belongs to a middle region between a conductor and an insulator and refers to a material that conducts electricity under predetermined conditions. Various semiconductor devices, for example, a memory device and the like may be manufactured using the semiconductor material. The memory device may be divided into a volatile memory device and a non-volatile memory device. In the case of the non-volatile memory device, its contents may not be deleted even when power is turned off, and it can be used in various electronic devices such as portable phones, digital cameras, and PCs.

In accordance with the recent increase in storage capacity, there is a need for improved integration of non-volatile memory devices. Integration of memory devices placed two-dimensionally on a flat surface may be limited. Accordingly, a vertical non-volatile memory device that is arranged three-dimensionally is being proposed.

### SUMMARY

Embodiments are intended to provide a semiconductor device with improved reliability and an electronic system including the same.

According to an aspect of the present disclosure, a semiconductor device includes a substrate, a stacking structure disposed on the substrate and including a plurality of gate electrodes that are stacked on each other in a vertical direction and are spaced apart from each other, wherein the vertical direction is perpendicular to an upper surface of the substrate, a first channel structure penetrating the plurality of gate electrodes and including a first channel layer extending lengthwise in the vertical direction and a first ferroelectric layer including a vertical portion disposed between the first channel layer and a side surface of the stacking structure and a horizontal portion disposed on an upper surface of the stacking structure, an insulation pattern disposed on the upper surface of the stacking structure, a contact pad that penetrates the insulation pattern and is connected to the first channel structure, a selection gate electrode disposed on the insulation pattern, and a second channel structure that penetrates the selection gate electrode, is connected to the contact pad, and extends lengthwise in the vertical direction. The contact pad is disposed in a space between the second channel structure and the first channel structure. The contact pad includes a first portion that penetrates the insulation pattern and contacts an upper surface of the first channel layer, a second portion that penetrates the horizontal portion of the first ferroelectric layer and contacts an exterior surface of the first channel layer, and a third portion that protrudes from a bottom surface of the second portion and contacts the exterior surface of the first channel layer.

According to an aspect of the present disclosure, a semiconductor device includes a substrate, a stacking structure disposed on the substrate and including a plurality of gate electrodes that are stacked on each other and are spaced apart from each other, a first channel structure that penetrates the plurality of gate electrodes of the stacking structure, and includes a first channel layer extending in a vertical direction perpendicular to an upper surface of the substrate, a first ferroelectric layer including a vertical portion disposed between the first channel layer and a side surface of the stacking structure and a horizontal portion disposed on an upper surface of the stacking structure, and a first insulation layer disposed between the first ferroelectric layer and the stacking structure, an insulation pattern disposed on the upper surface of the stacking structure, a contact pad that penetrates the insulation pattern and is connected to the first channel structure, a selection gate electrode disposed on the insulation pattern, and a second channel structure that penetrates the selection gate electrode and is connected to the contact pad. The second channel structure includes a second channel layer extending in the vertical direction and a second ferroelectric layer disposed between the second channel layer and the selection gate electrode. The contact pad includes a first portion penetrating the insulation pattern, a second portion penetrating the horizontal portion of the first ferroelectric layer, and a third portion protruded from a bottom surface of the second portion and contacting an exterior surface of the first channel layer.

According to an aspect of the present disclosure, an electronic system includes a first substrate, a semiconductor device disposed on the first substrate, and a controller that is disposed on the first substrate and electrically connected to the semiconductor device. The semiconductor device includes a peripheral circuit region, a cell region that includes an input/output connection wire electrically connected to the peripheral circuit region, and an input/output pad that is electrically connected to the input/output connection wire extending into the cell region. The cell region includes a second substrate, a stacking structure disposed on the second substrate and including a plurality of gate electrodes that are stacked on each other and are spaced apart from each other, a first channel structure that penetrates the plurality of gate electrodes of the stacking structure, and includes a first channel layer extending in a vertical direction perpendicular to an upper surface of the second substrate and a first ferroelectric layer including a vertical portion disposed between the first channel layer and a side surface of the stacking structure and a horizontal portion disposed on an upper surface of the stacking structure, an insulation pattern disposed on the upper surface of the stacking structure, a contact pad that penetrates the insulation pattern and is connected to the first channel structure, a selection gate electrode disposed on the insulation pattern, and a second channel structure that penetrates the selection gate electrode and contacts the contact pad, and extends in the vertical direction. The contact pad includes a first portion that penetrates the insulation pattern and contacts an upper surface of the first channel layer, a second portion that penetrates the horizontal portion of the first ferroelectric layer and contacts an exterior surface of the first channel layer, and a third portion that is protruded from a bottom surface of the second portion and contacts the exterior surface of the first channel layer.

In the semiconductor devices according to the embodiments, the contact area between the contact pad and the first channel pad is increased, thereby stably connecting the first channel structure and the second channel structure. Accordingly, the reliability of the semiconductor device can be improved.

### BRIEF DESCRIPTION OF THE DRAWINGS

FIG. 1 is a top plan view of a semiconductor device according to some embodiments.

FIG. 2 is an enlarged top plan view of the area A of FIG. 1.

FIG. 3 is an enlarged cross-sectional view of FIG. 1, taken along the line I-I′.

FIG. 4 is an enlarged cross-sectional view of the area B1 of FIG. 3.

FIG. 5 is a top plan view of a channel structure of a semiconductor device according to some embodiments.

FIG. 6 to FIG. 14 are cross-sectional views of a semiconductor device according to some embodiments, corresponding to the area B1 of FIG. 3.

FIG. 15 and FIG. 16 are cross-sectional views of a semiconductor device according to some embodiments.

FIG. 17 to FIG. 19 are cross-sectional views of a method of manufacturing a semiconductor device according to some embodiments.

FIG. 20 is an enlarged cross-sectional view of the area B2 of FIG. 19.

FIG. 21 and FIG. 22 are cross-sectional views of a method of manufacturing a semiconductor device according to some embodiments.

FIG. 23 is an enlarged cross-sectional view of the area B3 of FIG. 22.

FIG. 24 to FIG. 33 show a method of manufacturing a semiconductor device according to some embodiments, and are cross-sectional views corresponding to the area B3 of FIG. 15.

FIG. 34 illustrates an electronic system including a semiconductor device according to some embodiments.

FIG. 35 is a perspective view of an electronic system including a semiconductor device according to some embodiments.

FIG. 36 and FIG. 37 are cross-sectional views of a semiconductor package according to some embodiments.

### DETAILED DESCRIPTION

Hereinafter, with reference to accompanying drawings, various embodiments will be described in detail and thus a person of an ordinary skill can easily practice them in the technical field to which the present invention belongs. The present invention may be embodied in many different forms and is not limited to the embodiments described herein.

In order to clearly explain the present invention, parts irrelevant to the description have been omitted, and the same reference numerals should be attached to the same or similar constituent elements throughout the specification.

In addition, since the size and thickness of each component shown in the drawing is arbitrarily shown for convenience of description, the present invention is not necessarily limited to what is shown. In the drawings, the thickness of layers, films, panels, regions, etc., are exaggerated for clarity. In addition, in the drawing, for convenience of explanation, the thickness of some layers and regions is exaggerated. However, the relative dimensions and/or positions of each component in the drawings reflects the present invention.

It will be understood that when an element such as a layer, film, region, or substrate is referred to as being “on” another element, it can be directly on the other element or intervening elements may also be present. In contrast, when an element is referred to as being “directly on” another element, there are no intervening elements present. Further, throughout the specification, the word “on” in reference to a target element will be understood to mean positioned above or below the target element, and will not necessarily be understood to mean positioned “at an upper side” relative to the direction opposite to gravity.

In addition, unless explicitly described to the contrary, the word “comprise”, and variations such as “comprises” or “comprising”, will be understood to imply the inclusion of stated elements but not the exclusion of any other elements.

Further, throughout the specification, the phrase “on a plane” means viewing a target portion from the top, and the phrase “on a cross-section” means viewing a cross-section formed by vertically cutting a target portion from the side.

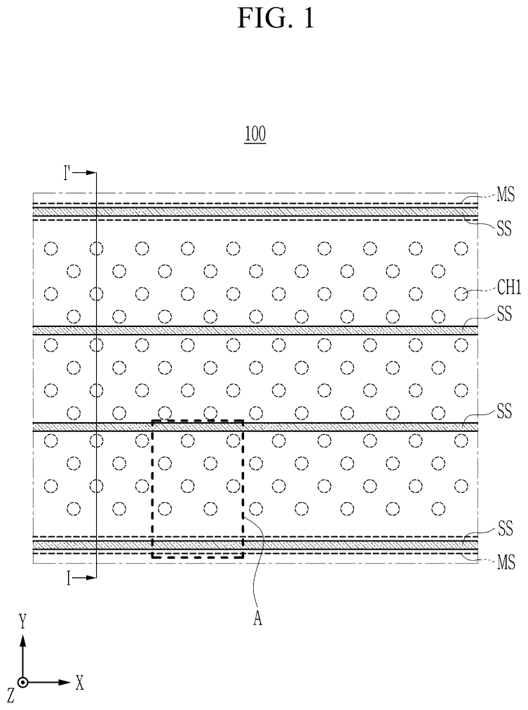

Hereinafter, a semiconductor device according to some embodiments will be described with reference to FIG. 1 to FIG. 5.

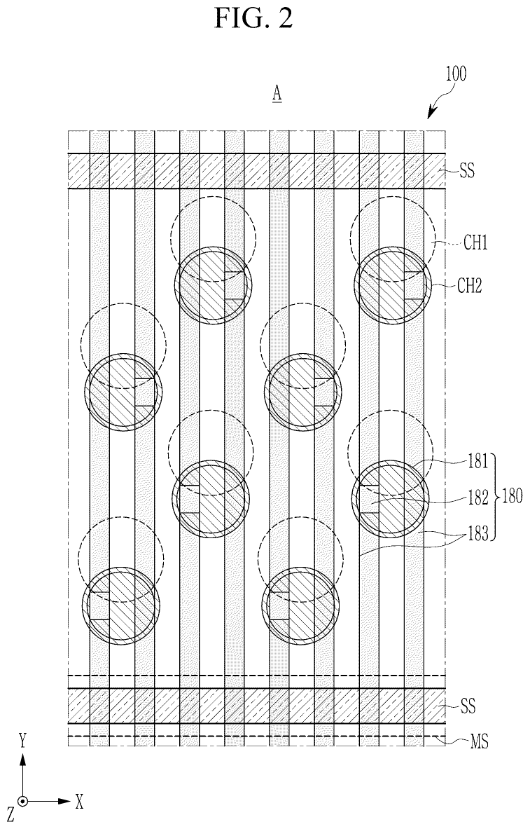

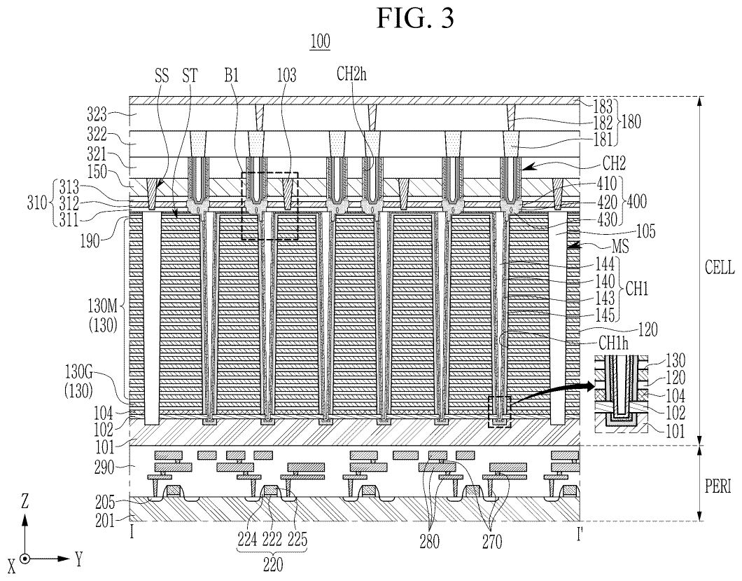

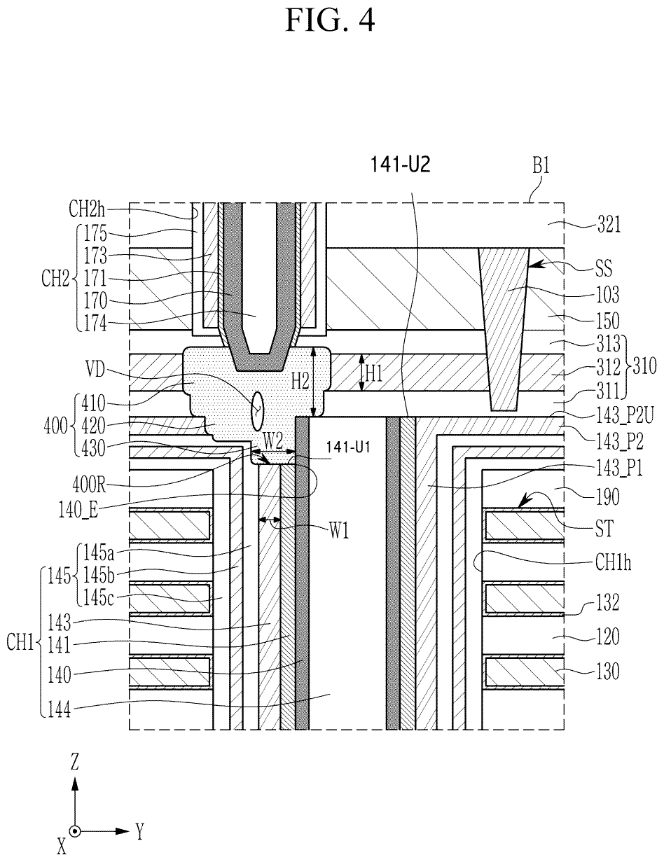

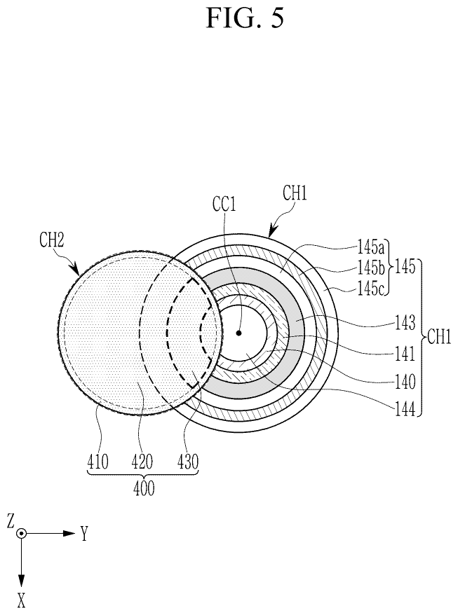

FIG. 1 is a top plan view of a semiconductor device according to an embodiment. FIG. 2 is an enlarged top plan view of the area A of FIG. 1. FIG. 3 is an enlarged cross-sectional view of FIG. 1, taken along the line I-I′. FIG. 4 is an enlarged cross-sectional view of the area B1 of FIG. 3. FIG. 5 is a top plan view of a channel structure of a semiconductor device according to an embodiment. In FIG. 5, for better understanding and ease of description, a vertical portion 143_P1 of a first ferroelectric layer 143 and a vertical portion of a first insulation layer 145 are illustrated, and a horizontal portion 143_P2 of the first ferroelectric layer 143 and a horizontal portion of the first insulation layer 145 are not illustrated.

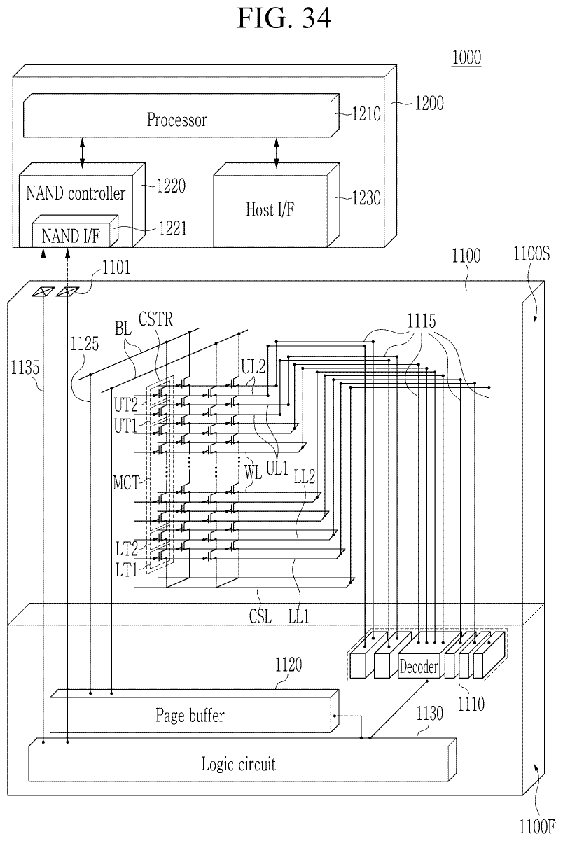

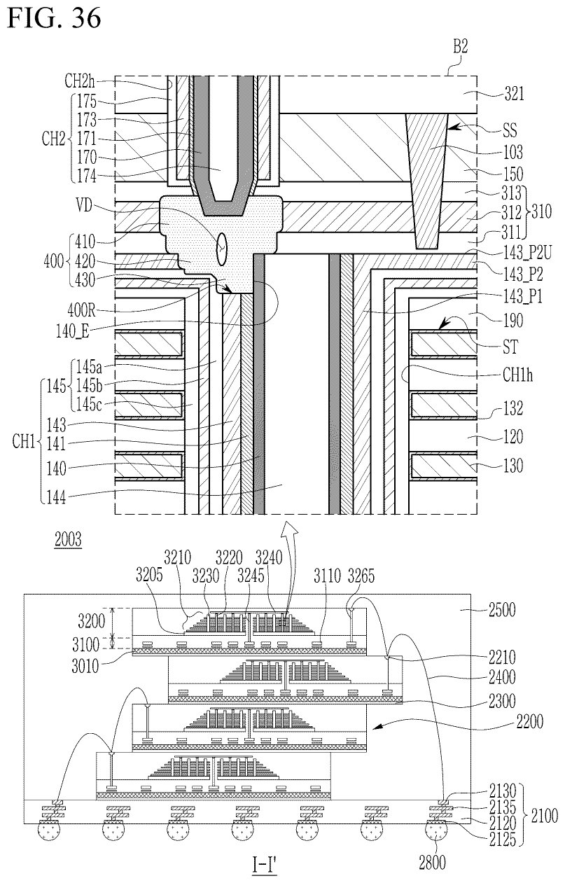

First, referring to FIG. 1 to FIG. 3, a semiconductor device 100 according to an embodiment may include a memory cell region CELL and a peripheral circuit region PERI that are vertically stacked. For example, the peripheral circuit region PERI and the cell region CELL may respectively be portions corresponding to a first structure 1100F and a second structure 1100S of a semiconductor device 1100 included in an electronic system 1000 shown in FIG. 34. In some embodiments, the peripheral circuit region PERI and cell region CELL may respectively be portions including a first structure 3100 and a second structure 3200 of a semiconductor chip 2200 shown in FIG. 36.

The memory cell region CELL may be disposed at an upper end of the peripheral circuit region PERI. However, this is not restrictive, and in some embodiments, the semiconductor device 100 may be disposed on one substrate and the memory cell region CELL and the peripheral circuit region PERI may be separated from each other. In other words, the memory cell region CELL and peripheral circuit region PERI may not overlap vertically. In some cases, the memory cell region CELL may be disposed at a lower end of the peripheral circuit region PERI.

The peripheral circuit region PERI may include a base substrate 201, circuit elements 220, circuit contact plugs 270, and circuit wire lines 280 disposed on the base substrate 201.

The base substrate 201 may have an upper surface extending in a first direction (X direction) and a second direction (Y direction). Separate device isolation layers are formed on the base substrate 201 such that an active region can be defined. Source/drain regions 205, including impurities, may be disposed in a part of the active region. The base substrate 201 may include a semiconductor material, for example, a group IV semiconductor, a group III-V compound semiconductor, or a group II-VI compound semiconductor. The base substrate 201 may be provided as a bulk wafer or an epitaxial layer. However, this is not restrictive thereto.

The circuit elements 220 may include a horizontal transistor. Each of the circuit elements 220 may include a circuit gate dielectric layer 222, a spacer layer 224, and a circuit gate electrode 225. The source/drain regions 205 may be disposed on opposite sides of the circuit gate electrode 225.

The peripheral area insulation layer 290 may be disposed above the circuit element 220 on the base substrate 201. The circuit contact plugs 270 may penetrate the peripheral area insulation layer 290 and may be connected to the source/drain regions 205.

An electrical signal may be applied to the circuit element 220 by the circuit contact plugs 270. In a region not shown, the circuit contact plugs 270 may also be connected to the circuit gate electrode 225. The circuit wire lines 280 may be connected to the circuit contact plugs 270, and may be provided as a plurality of layers.

In an embodiment, in the semiconductor device 100, the peripheral circuit region PERI is first manufactured, and then the substrate 101 of the memory cell region CELL is formed on the memory cell region CELL such that the memory cell region CELL can be manufactured. The substrate 101 may have the same size as the base substrate 201 or may be formed smaller than the base substrate 201.

The memory cell region CELL may include a substrate 101, first and second horizontal conductive layers 102 and 104 disposed on the substrate 101, a stacking structure ST, a first channel structure CH1, an insulation pattern 310, a selection gate electrode 150, a second channel structure CH2, and a contact pad 400. Here, the stacking structure ST may include a plurality of gate electrodes 130 and interlayer insulation layers 120 that are alternately stacked on each other.

The substrate 101 may have an upper surface extending in the first direction (X direction) and the second direction (Y direction). The substrate 101 may include a semiconductor material, for example a group IV semiconductor, a group III-V compound semiconductor, or a group II-VI compound semiconductor. For example, the group IV semiconductors may include silicon, germanium, or silicon-germanium. The substrate 101 may be provided as a bulk wafer, an epitaxial layer, a silicon on insulator (SOI) layer, or a semiconductor on insulator (SeOI) layer. However, this is not restrictive thereto.

The first and second horizontal conductive layers 102 and 104 may be stacked on an upper surface of the substrate 101. The first horizontal conductive layer 102 may serve as at least a part of a common source line of the semiconductor device 100 and, for example, may serve as a common source line together with the substrate 101. As shown in the enlarged view of FIG. 3, the first horizontal conductive layer 102 may be directly connected to a first channel layer 140.

The first and second horizontal conductive layers 102 and 104 may include a semiconductor material, and, for example, may include polycrystalline silicon. In this case, at least the first horizontal conductive layer 102 may be a layer doped with impurities of the same conductivity type as the substrate 101, and the second horizontal conductive layer 104 may be a doped layer or may contain impurities diffused from the first horizontal conductive layer 102. However, the material of the second horizontal conductive layer 104 is not limited to the semiconductor material, and in some embodiments, it may be replaced with an insulation layer.

The plurality of gate electrodes 130 may be spaced apart in a third direction (Z direction) on the substrate 101 to form the stacking structure ST. The plurality of gate electrodes 130 may include a ground gate electrode 130G forming a gate of the ground selection transistor and memory gate electrodes 130M forming a plurality of memory cells. Depending on the capacity of the semiconductor device 100, the number of memory gate electrodes 130M that form the memory cells may be determined. For example, the ground gate electrodes 130G may be one or two or more, and may have the same or different structure as the memory gate electrodes 130M.

In some embodiments, the plurality of gate electrodes 130 may further include a gate electrode that is disposed below the ground gate electrode 130G and that forms an erase transistor used in an erase operation using a gate induced leakage current (GIDL) phenomenon. In addition, some of the plurality of gate electrodes 130 (e.g., memory gate electrodes 130M adjacent to the ground gate electrode 130G) may be dummy gate electrodes.

The semiconductor device 100 according to an embodiment may further include a gate dielectric layer 132 surrounding each of the plurality of gate electrodes 130. The gate dielectric layer 132 may be disposed between the plurality of gate electrodes 130 and the interlayer insulation layers 120 and between the plurality of gate electrodes 130 and the first channel structure CH1.

The interlayer insulation layers 120 is disposed between the plurality of gate electrodes 130, and may be alternately disposed with the plurality of gate electrodes 130 in the third direction (Z direction). Like the plurality of gate electrodes 130, the interlayer insulation layers 120 may be disposed apart from each other in the third direction (Z direction) on the upper surface of the substrate 101. The interlayer insulation layers 120 may include or may be formed of insulating materials such as silicon oxide and silicon nitride, but are not limited thereto.

Each of the first channel structures CH1 forms one memory cell string, and the first channel structures CH1 may be disposed spaced apart from each other in rows and columns on the substrate 101. For example, the first channel structures CH1 may be disposed to form a lattice pattern on a plane, and each of the first channel structures CH1 may be disposed where the first direction (X direction) and the second direction (Y direction) intersect. In some embodiments, the first channel structures CH1 may be disposed in a zigzag shape in one direction. As an example as shown in FIG. 1, between two adjacent separation regions MS, twelve first channel structures CH1 are arranged zigzag in a first column and twelve channel structures are arranged in a second column. However, this is not restrictive thereto, and the arrangement form of the first channel structures CH1 may be changed in various ways.

Each of the first channel structures CH1 may be provided within a first channel hole CH1h penetrating the stacking structure ST. That is, the first channel structure CH1 may extend in the third direction (Z direction). Each of the first channel structures CH1 has a pillar shape, and depending on the aspect ratio, it may have an inclined side surface and may have a decreasing width as it approaches the substrate 101 (i.e., in a direction toward the substrate 101), but is not limited thereto.

Further referring to FIG. 4, the first channel structure CH1 of the semiconductor device 100 according to an embodiment may include a first core insulation layer 144, a first channel layer 140, a first channel insulation layer 141, first ferroelectric layer 143, and a first insulation layer 145.

The first core insulation layer 144 is provided at a central area of the first channel structure CH1, and the first channel layer 140 may surround a sidewall of the first core insulation layer 144. For example, the first core insulation layer 144 may have a pillar shape (for example, a circular cylinder shape or a polygonal pillar shape), and the first channel layer 140 may have a planar shape such as an annular shape. However, the embodiment is not limited to this, and for example, the first core insulation layer 144 may be omitted, and the first channel layer 140 may have a pillar shape (for example, a circular cylinder shape or a polygonal pillar shape).

In an embodiment, a portion of the first channel layer 140 and at least a portion of the first core insulation layer 144 may be in contact with the contact pad 400. The term “contact,” or “in contact with,” as used herein, refers to a direct connection (i.e., physical touching) unless the context indicates otherwise. For example, a portion of an upper surface of the first channel layer 140 and a portion of an upper surface of the first core insulation layer 144 may be in contact with a first portion 410 of the contact pad 400, and a portion of the remaining portion of the upper surface of the first channel layer 140 and a portion of the remaining portion of the upper surface of the first core insulation layer 144 may be in contact with the insulating pattern 310. In addition, a part of an exterior side 140E of the first channel layer 140 may be in contact with the contact pad 400. Accordingly, the first channel layer 140 may be electrically connected to the contact pad 400. A detailed description of this will be provided later in the description of contact pad 400.

The first horizontal conductive layer 102 and the second horizontal conductive layer 104 may penetrate the first insulation layer 145, the first ferroelectric layer 143, and the first channel insulation layer 141 to contact the first channel layer 140. In some embodiments, as shown in FIG. 3, the first horizontal conductive layer 102 may penetrate the first insulation layer 145, the first ferroelectric layer 143, and the first channel insulation layer 141 to contact the first channel layer 140. In FIG. 3, the first channel insulation layer 141 may be omitted for the simplicity of drawing. The first channel layer 140 may be electrically connected to the first horizontal conductive layer 102 and the second horizontal conductive layer 104. For example, as shown in FIG. 3, a portion of the side of the first channel layer 140 may be electrically connected to the first horizontal conductive layer 102 by contacting a side surface of the first horizontal conductive layer 102.

The first channel layer 140 may include or may be formed of a semiconductor material, for example, polycrystalline silicon. Here, the semiconductor material may be undoped with impurities or may be doped with a P-type or N-type impurity. The first core insulation layer 144 may include various insulating materials. For example, the first core insulation layer 144 may include or may be formed of silicon oxide, silicon oxynitride, or a combination thereof. However, the materials of first channel layer 140 and the first core insulation layer 144 are not limited thereto.

The first channel insulation layer 141 may surround the first channel layer 140. At least a part of an upper surface of the first channel insulation layer 141 may contact the contact pad 400. A part of the remaining of the upper surface of the first channel insulation layer 141 may contact the insulation pattern 310. As an example, the remaining portion of the upper surface of the first channel insulation layer 141 may be in contact with the first insulation pattern 311. The first channel insulation layer 141 may include various insulating materials. For example, the first channel insulation layer 141 may include or may be formed of silicon oxide or silicon oxynitride. In some embodiments, the first channel insulation layer 141 may have a U-shaped layer having two upper ends on a cross-sectional view taken line I-I′. A first upper end 141-U1 of the two upper ends may be lower than a second upper end 141-U2 of the two upper ends. The first upper end 141-U1 of the first channel insulation layer 141 may contact the contact pad 400 (e.g., a third portion 430 of the contact pad 400, which will be described below), and the second upper end 141-U2 of the first channel insulation layer 141 may contact the first insulation pattern 311.

The first ferroelectric layer 143 may further surround the first channel insulation layer 141. The first ferroelectric layer 143 may be disposed between the plurality of gate electrodes 130 and the first channel insulation layer 141 and between the interlayer insulation layers 120 and the first channel insulation layer 141. The first ferroelectric layer 143 may be disposed between the first channel insulation layer 141 and the plurality of gate electrodes 130.

The first ferroelectric layer 143 of the semiconductor device according to an embodiment may include a vertical portion 143_P1 disposed between the first channel layer 140 and the stacking structure ST and a horizontal portion 143_P2 disposed on the stacking structure ST. In some embodiments, the vertical portion 143_P1 may be disposed in a space between the first channel layer 140 and a side surface of the stacking structure ST, and the horizontal portion 143_P2 may be disposed on an upper surface of the stacking structure ST.

The vertical portion 143_P1 of the first ferroelectric layer 143 may be surrounded by the first channel insulation layer 141. That is, the vertical portion 143_P1 may be disposed between the plurality of gate electrodes 130 and the first channel insulation layer 141 and between the interlayer insulation layers 120 and the first channel insulation layer 141. The vertical portion 143_P1 may be disposed between the first channel layer 140 and the plurality of gate electrodes 130.

The horizontal portion 143_P2 of the first ferroelectric layer 143 may be disposed on the stacking structure ST. For example, the horizontal portion 143_P2 may be disposed on a first insulation layer 145 of the stacking structure ST, which will be described later. The horizontal portion 143_P2 may be disposed between the insulation pattern 310 and the stacking structure ST. For example, the horizontal portion 143_P2 may be disposed between the first insulation pattern 311 and the first insulation layer 145. The horizontal portion 143_P2 may be in contact with a bottom surface of the first insulation pattern 311 and an upper surface of the first insulation layer 145.

In an embodiment, the horizontal portion 143_P2 may extend in the first direction (X direction) and second direction (Y direction). For example, the horizontal portion 143_P2 may extend in the first direction (X direction) and second direction (Y direction) and may connect between adjacent first channel structures CH1 in the horizontal direction (e.g., first direction (X direction) and/or second direction (Y direction)). For example, as shown in FIG. 3, the first channel structure CH1 is provided in plural, and the horizontal portion 143_P2 may extend in the second direction (Y direction) between two first channel structures CH1 adjacent in the second direction (Y direction). In an embodiment, the vertical portion 143_P1 and the horizontal portion 143_P2 of the first ferroelectric layer 143 may be integrally formed. That is, the vertical portion 143_P1 and the horizontal portion 143_P2 may be integrally formed by the same process.

In an embodiment, a part of the first ferroelectric layer 143 may be in contact with the contact pad 400. For example, an upper surface of the vertical portion 143_P1 of the first ferroelectric layer 143 may be in contact with a third portion 430 of the contact pad 400, and the horizontal portion 143_P2 of the first ferroelectric layer 143 may be in contact with a second portion 420 of the contact pad 400. This may be due to the process characteristic of etching a portion of the first ferroelectric layer 143 and forming the contact pad 400 within the etched space. For example, the contact between the contact pad 400 and other elements such as the first ferroelectric layer 143 may be attributed to the following process integration: etching a portion of the first ferroelectric layer 143; and forming the contact pad 400 within the etched space.

The first ferroelectric layer 143 may include or may be formed of a ferroelectric material. For example, the first ferroelectric layer 143 may include or may be formed of a Hafnium (Hf) compound with ferroelectric characteristics. For example, the first ferroelectric layer 143 may contain or may be formed of HfO₂, HfZnO, HfSiO, HfSiON, HfTaO, HfTIO, HfZrO, or a combination thereof. In some embodiments, the first ferroelectric layer 143 may include or may be formed of, for example, a ferroelectricity material with a perovskite structure, such as PZT (PbZrxTi1-xO₃), BaTiO₃, and PbTiO₃. The first ferroelectric layer 143 may include at least one dopant selected from carbon (C), silicon (Si), magnesium (Mg), aluminum (Al), yttrium (Y), nitrogen (N), germanium (Ge), tin (Sn), strontium (Sr), lead (Pb), calcium (Ca), barium (Ba), titanium (Ti), zirconium (Zr), gadolinium (Gd), and lanthanum (La). In addition, the first ferroelectric layer 143 may be made of crystalline. For example, the first ferroelectric layer 143 may have a crystal structure of an orthorhombic system. In an embodiment, the first ferroelectric layer 143 may include a different material from the first insulation layer 145, the insulation pattern 310, and the first channel layer 140. The first ferroelectric layer 143 may include or may be formed of a material having etch selectivity with respect to the first insulation layer 145, the insulation pattern 310, and the first channel layer 140.

In an embodiment, when the first ferroelectric layer 143 includes a ferroelectric material, the first ferroelectric layer 143 may be configured to have various states of polarization depending on a voltage applied between the plurality of gate electrodes 130 and the first channel layer 140. Specifically, residual polarization may be generated within the first ferroelectric layer 143 by a voltage applied between the plurality of gate electrodes 130 and the first channel structure CH1. Here, the size of the remnant polarization generated within the first ferroelectric layer 143 may be determined not only by the size of the voltage applied between the plurality of gate electrodes 130 and the first channel layer 140, but also by a polarization-voltage (PV) hysteresis characteristic of the remnant polarization that is generated within the first ferroelectric layer 143 and remains when an applied electric field is reduced to zero. The generated remanent polarization that is stored in the first ferroelectric layer 143 may be non-volatile, and may represent signal information to be stored. In other words, the first ferroelectric layer 143 may serve as a non-volatile memory layer.

The first insulation layer 145 may surround the first ferroelectric layer 143. The first insulation layer 145 may be extended to have a conformal shape along the inner sidewall of the first channel hole CH1h. The first insulation layer 145 may be disposed to cover a bottom surface and the inner sidewall of the first channel hole CH1h. In addition, the first insulation layer 145 may be disposed on the cell region insulation layer 190. The first insulation layer 145 may be disposed between the first ferroelectric layer 143 and the stacking structure ST. For example, the first insulation layer 145 may be disposed between the vertical portion 143_P1 of the first ferroelectric layer 143 and a side surface of the stacking structure ST and between the horizontal portion 143_P2 of the first ferroelectric layer 143 and an upper surface of the stacking structure ST. The first insulation layer 145 may be disposed between the plurality of gate electrode 130 and the vertical portion 143_P1, between the interlayer insulation layers 120 and the vertical portion 143_P1, and between the cell region insulation layer 190 and the horizontal portion 143_P2. The first insulation layer 145 may be disposed between the first ferroelectric layer 143 and the gate electrode 130.

In an embodiment, at least a part of the first insulation layer 145 may be in contact with the contact pad 400. For example, at least a part of an upper surface of the first insulation layer 145 may be in contact with the third portion 430 of the contact pad 400, and a part of the remaining of the upper surface of the first insulation layer 145 may be in contact with the insulation pattern 310. This may be due to the process characteristic of etching at least a part of the first insulation layer 145 disposed below the insulation pattern 310 and forming the contact pad 400 within the etched space. For example, the contact between the contact pad 400 and other elements such as the first insulation layer 145 may be attributed to the following process integration: etching at least a part of the first insulation layer 145 disposed below the insulation pattern 310 and forming the contact pad 400 within the etched space.

The first insulation layer 145 of the semiconductor device 100 according to an embodiment may include a first blocking layer 145a, a charge inflow layer 145b, and a second blocking layer 145c that sequentially surround the first ferroelectric layer 143.

The first blocking layer 145a may be disposed on an external side surface of the vertical portion 143_P1 of the first ferroelectric layer 143 and the bottom surface of the horizontal portion 143_P2 of the first ferroelectric layer 143. The first blocking layer 145a may be disposed between the first ferroelectric layer 143 and the stacking structure ST. For example, the first blocking layer 145a may be disposed between the vertical portion 143_P1 of the first ferroelectric layer 143 and the side surface of the stacking structure ST and between the horizontal portion 143_P2 of the first ferroelectric layer 143 and the upper surface of the stacking structure ST. The first blocking layer 145a may be disposed between the plurality of gate electrode 130 and the vertical portion 143_P1, between the interlayer insulation layers 120 and the vertical portion 143_P1, and between the cell region insulation layer 190 and the horizontal portion 143_P2. The first blocking layer 145a may include various insulating materials. The first blocking layer 145a may include or may be formed of silicon oxide or silicon oxynitride, but is not limited thereto.

The charge inflow layer 145b may surround the first blocking layer 145a. The charge inflow layer 145b may be disposed between the first blocking layer 145a and the stacking structure ST. For example, the charge inflow layer 145b may be disposed between the plurality of gate electrodes 130 and the first blocking layer 145a, between the interlayer insulation layers 120 and the first blocking layer 145a, and between the cell region insulation layer 190 and the first blocking layer 145a. The charge inflow layer 145b may include various insulating materials. The charge inflow layer 145b may include a different material from the first blocking layer 145a. For example, the charge inflow layer 145b may include or may be formed of silicon nitride, but is not limited thereto.

In this case, according to an embodiment, an electric field may be concentrated at the charge inflow layer 145b according to a voltage applied to the plurality of gate electrodes 130. Accordingly, charges can easily flow into the charge inflow layer 145b, and thus the generation of residual polarization of the first ferroelectric layer 143 can be facilitated. In other words, although the voltage applied to the plurality of gate electrodes 130 is reduced, the electric field is concentrated at the charge inflow layer 145b, and thus residual polarization can be easily generated at the first ferroelectric layer 143.

The second blocking layer 145c may surround the charge inflow layer 145b. The second blocking layer 145c may be disposed between the charge inflow layer 145b and the stacking structure ST. For example, the second blocking layer 145c may be disposed between the plurality of gate electrodes 130 and the charge inflow layer 145b, between the interlayer insulation layers 120 and the charge inflow layer 145b, and between the cell region insulation layer 190 and the charge inflow layer 145b. The second blocking layer 145c may include various insulating materials. The second blocking layer 145c may include a different material from the charge inflow layer 145b. For example, the second blocking layer 145c may include or may be formed of silicon oxide or silicon oxynitride, but is not limited thereto.

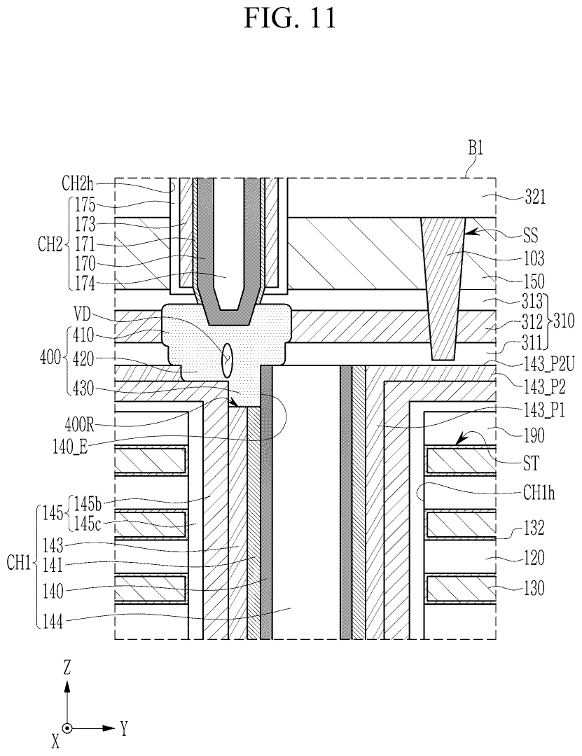

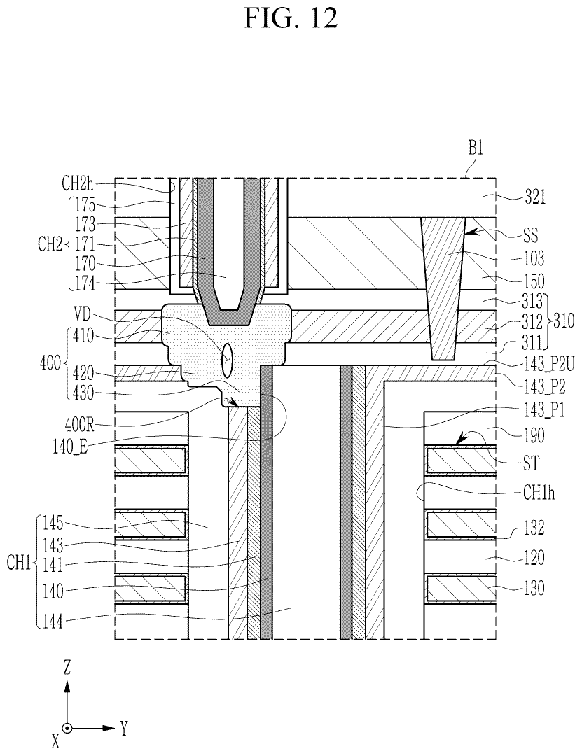

In an embodiment, the first insulation layer 145 may be formed of multiple layers, but is not limited thereto. For example, the first insulation layer 145 may be formed of a single layer. This will be described later with reference to FIG. 11 and FIG. 12.

The semiconductor device 100 according to an embodiment may further include separation regions MS.

The separation regions MS may penetrate the horizontal portion 143_P2 of the first ferroelectric layer 143, the first insulation layer 145, the cell region insulation layer 190, the stacking structure ST formed of the plurality of gate electrodes 130 and the interlayer insulation layers 120, the first horizontal conductive layer 102, and the second horizontal conductive layer 104. The separation regions MS extend in the third direction (Z direction) and may be connected to the substrate 101.

As shown in FIG. 3, the separation regions MS may be disposed parallel and spaced apart from each other along the second direction (Y direction). The separation regions MS may separate the plurality of gate electrodes 130 from each other in the second direction (Y direction).

The separation regions MS may have a shape of which a width decreases toward the substrate 101 due to the high aspect ratio. A separation insulation layer 105 may be disposed within the separation regions MS. The separation insulation layer 105 may include or may be formed of at least a silicon oxide, silicon nitride, and silicon oxynitride. However, the present disclosure is not limited to this, and in some embodiments, a conductive material layer may be disposed within the separation regions MS.

The semiconductor device 100 according to an embodiment may further include a cell region insulation layer 190.

The cell region insulation layer 190 may cover the stacking structure ST formed of the plurality of gate electrodes 130 and the interlayer insulation layers 120. The cell region insulation layer 190 may be disposed between the horizontal portion 143_P2 of the first ferroelectric layer 143 and the upper surface of the stacking structure ST. The cell region insulation layer 190 may cover at least a portion of the separation regions MS and/or the side surfaces of the first channel structure CH1, for example, a portion extending upward from the stacking structure ST.

The cell region insulation layer 190 may include at least one of silicon oxide, silicon nitride, and silicon oxynitride. However, this is not restrictive thereto.

The insulation pattern 310 may be disposed on the stacking structure ST. The insulation pattern 310 may be disposed on the first channel structure CH1 and the separation regions MS. For example, the insulation pattern 310 may be disposed on the horizontal portion 143_P2 of the first ferroelectric layer 143 and the separation regions MS. The insulation pattern 310 may extend in the first direction (X direction) and the second direction (Y direction). The insulation pattern 310 may be in contact with the first channel structure CH1. For example, as described above, the insulation pattern 310 may be in contact with the first core insulation layer 144, the first channel layer 140, and the first ferroelectric layer 143. In some embodiments, the insulation pattern 310 may contact the upper surface of the first channel structure CH1.

The insulation pattern 310 according to an embodiment may include first to third insulation patterns 311 to 313 that are sequentially disposed on the first channel structure CH1.

The first insulation pattern 311 may be disposed on the first channel structure CH1 and the separation regions MS. For example, the first insulation pattern 311 may be disposed on the horizontal portion 143_P2 of the first ferroelectric layer 143. The first insulation pattern 311 may extend in the first direction (X direction) and the second direction (Y direction). The first insulation pattern 311 may be in contact with an upper surface of the first core insulation layer 144, an upper surface of the first channel layer 140, and an upper surface 143_P2U of the horizontal portion 143_P2 of the first ferroelectric layer 143. The first insulation pattern 311 may include or may be formed of silicon oxide or silicon oxynitride, but is not limited thereto.

The second insulation pattern 312 may be disposed on the first insulation pattern 311. The second insulation pattern 312 may extend in the first direction (X direction) and the second direction (Y direction). The second insulation pattern 312 may include a different material from the cell region insulation layer 190, the first insulation pattern 311, and the third insulation pattern 313, which will be described later. The second insulation pattern 312 may include a material having etch selectivity with respect to the cell region insulation layer 190, the first insulation pattern 311, and the third insulation pattern 313, which will be described later. For example, the second insulation pattern 312 may include or may be formed of silicon nitride but is not limited thereto.

The third insulation pattern 313 may be disposed on the second insulation pattern 312. The second insulation pattern 312 may extend in the first direction (X direction) and the second direction (Y direction). The third insulation pattern 313 may include or may be formed of silicon oxide or silicon oxynitride, but is not limited thereto.

In an embodiment, at least a portion of the insulation pattern 310 may be penetrated by an upper isolation region SS, which will be described later. For example, the second insulation pattern 312 may be penetrated by the upper separation region SS. Accordingly, even though the second insulation pattern 312 of the semiconductor device 100 according to an embodiment has an integrated structure which continuously extends on a plane, a residual material generated during the manufacturing process may be discharged through the upper separation region SS. For example, before the upper separation region SS is filled with an upper separation layer 103 in a fabrication process of forming the semiconductor device 100, the residual material generated in a process of forming a first expansion hole EH1 and a second expansion hole EH2 may be discharged through an opening of the second insulation pattern 312 corresponding to the upper separation region SS. The first and second expansion holes EH1 and HE2, and the upper separation layer 103 will be described later.

A selection gate electrode 150 may be disposed on the insulation pattern 310. For example, the selection gate electrode 150 may be disposed on the third insulation pattern 313. The selection gate electrode 150 may be disposed spaced apart from the first channel structure CH1 in the third direction (Z direction).

In an embodiment, the selection gate electrode 150 may include a different material than the plurality of gate electrodes 130. For example, the selection gate electrode 150 may be a semiconductor material layer such as polycrystalline silicon and the like. In this case, a thickness along the third direction (Z direction) of the selection gate electrode 150 may be thicker than a thickness along the third direction (Z direction) of each of the plurality of gate electrodes 130. The plurality of gate electrodes 130 may include at least one of a transition metal (e.g., Ti, Ta) and a metal nitride (e.g., TiN, TaN) thereof.

The selection gate electrode 150 may be a string selection line forming a string selection transistor (refer to UT1 and UT2 in FIG. 34).

In FIG. 3, one selection gate electrode 150 is illustrated, but this is not restrictive thereto. For example, a plurality of selection gate electrodes 150 may be provided. In this case, the plurality of selection gate electrodes 150 may be disposed apart from each other along the third direction (Z direction).

The semiconductor device 100 according to an embodiment may further include an upper separation region SS.

The upper separation region SS may penetrate at least a part of the selection gate electrode 150 and the insulation pattern 310. For example, the upper separation region SS may penetrate the selection gate electrode 150, the third insulation pattern 313, and the second insulation pattern 312 and may penetrate at least a part of the first insulation pattern 311, but this is not restrictive thereto. The upper separation region SS may extend in the first direction (X direction). In this case, an upper surface of the upper separation region SS and an upper surface of the selection gate electrode 150 may be positioned at the substantially same level. A bottom surface of the upper separation region SS may be positioned higher than the upper surface of the stacking structure ST.

In an embodiment, a gap between the separation regions MS adjacent in the second direction (Y direction) may be larger than a gap between the upper separation regions SS adjacent in the second direction (Y direction). That is, on a plane, at least some of the upper separation regions SS may be positioned between the separation regions MS adjacent in the second direction (Y direction).

Since the upper separation region SS and the selection gate electrode 150 are positioned at a higher level than the separation regions MS and the first channel structure CH1, dummy structures between the first channel structures CH1 may be omitted, and thus the semiconductor device 100 with improved integration can be provided.

An upper separation layer 103 may be disposed in the upper separation region SS. The upper separation layer 103 may include or may be formed of an insulating material such as silicon oxide. However, this is not restrictive thereto, and in some embodiments, the upper separation region SS may include at least some of the material of the second channel structure CH2, which will be described later.

The semiconductor device 100 according to an embodiment may further include first upper insulation layer 321 to the third upper insulation layer 323. The first upper insulation layer 321 to the third upper insulation layer 323 may be sequentially stacked on the selection gate electrode 150. The first upper insulation layer 321 to the third upper insulation layer 323 may include or may be formed of at least one of silicon oxide, silicon nitride, and silicon oxynitride.

Each of the second channel structures CH2 may be provided within a second channel hole CH2h penetrating the selection gate electrode 150. The second channel structure CH2 may be disposed on the first channel structure CH1. Each of the second channel structures CH2 extends in the third direction (Z direction) and thus may be electrically connected to the first channel structure CH1. The second channel structure CH2 may be a string selection channel structure of the string selection transistor (refer to UT1 and UT2 FIG. 34).

The second channel structures CH2 may be disposed in rows and columns on the insulation pattern 310 and spaced apart from each other. For example, the second channel structures CH2 can be disposed to form a lattice pattern on a plane, and each of the second channel structures CH2 may be disposed where the first direction (X direction) and the second direction (Y direction) intersect. In some embodiments, the second channel structures CH2 may be disposed in a zigzag shape in one direction.

In an embodiment, the second channel structure CH2 may be disposed spaced apart from the first channel structure CH1 in the second direction (Y direction). That is, at least a part of the second channel structure CH2 may overlap the first channel structure CH1 in the third direction (Z direction). For example, some regions of the second channel structure CH2 may overlap the first channel structure CH1, and other regions may overlap the cell region insulation layer 190. In other words, a center of the second channel structure CH2 may be spaced apart from a center of the first channel structure CH1 in the second direction (Y direction).

The second channel structure CH2 may have a pillar shape. Unlike the first channel structure CH1 described above, a width of the second channel structure CH2 may be constant. That is, a diameter of an upper surface of the second channel structure CH2 and a diameter of a bottom surface of the second channel structure CH2 may be substantially the same. However, the present invention is not limited thereto, and in some embodiments, the second channel structure CH2 may include an inclined side surface, and may have a decreasing width as it approaches the substrate 101 (i.e., in a direction toward the substrate 101).

In an embodiment, the second channel structure CH2 may include a second core insulation layer 174, a second channel layer 170 surrounding the second core insulation layer 174, a second ferroelectric layer 173 surrounding the second channel layer 170, and a second insulation layer 175 surrounding the second ferroelectric layer 173.

The second core insulation layer 174 is provided in a central region of second channel structure CH2, and the second channel layer 170 may surround a sidewall of the second core insulation layer 174. For example, the second core insulation layer 174 may have a pillar shape (for example, a circular cylinder shape or a polygonal pillar shape), and the second channel layer 170 may have a planar shape such as an annular shape. However, the embodiment is not limited to this, and for example, the second core insulation layer 174 may not be provided, and the second channel layer 170 may have a pillar shape (for example, a circular cylinder shape or a polygonal pillar shape). In addition, the second channel layer 170 may extend in the third direction (Z direction) inside the second channel hole CH2h.

In an embodiment, the second channel layer 170 may be in contact with the contact pad 400, which will be described later. For example, the bottom surface and a part of the side surface of the second channel layer 170 may be in contact with the contact pad 400, which will be described later. Accordingly, the second channel layer 170 may be electrically connected to the first channel layer 140 through the contact pad 400.

The second channel layer 170 may include or may be formed of a semiconductor material, for example, polycrystalline silicon. In some embodiments, the semiconductor material may be undoped with impurities. However, this is not limited thereto, and the second channel layer 170 may include a semiconductor material doped with a P-type or N-type impurity. The first core insulation layer 144 may include various insulating materials. For example, the second core insulation layer 174 may include or may be formed of silicon oxide, silicon oxynitride, or a combination thereof. However, the material of the second channel layer 170 and the first core insulation layer 144 are not limited thereto.

In an embodiment, as shown in FIG. 4, it is illustrated that the second channel layer 170 is formed of a single layer, but this is not restrictive thereto. For example, a portion of the second channel layer 170 and the remaining portion of the second channel layer 170 may be formed by separate processes.

The second channel insulation layer 171 may surround the second channel layer 170. The second channel insulation layer 171 may be disposed between the selection gate electrode 150 and the second channel layer 170. The second channel insulation layer 171 may have a similar structure and/or include the same material as the first channel insulation layer 141 of the first channel structure CH1, but it is not limited thereto. The second channel insulation layer 171 may include various insulating materials. For example, the second channel insulation layer 171 may include or may be formed of silicon oxide or silicon oxynitride.

The second ferroelectric layer 173 may surround at least a part of the second channel insulation layer 171. The second ferroelectric layer 173 may be disposed between the selection gate electrode 150 and the second channel insulation layer 171 and between the first upper insulation layer 321 and the second channel insulation layer 171. The second ferroelectric layer 173 may be disposed between the second channel insulation layer 171 and the selection gate electrode 150. The second ferroelectric layer 173 may have a similar structure and/or include the same material as the first ferroelectric layer 143 of the first channel structure CH1, but this is not restrictive thereto.

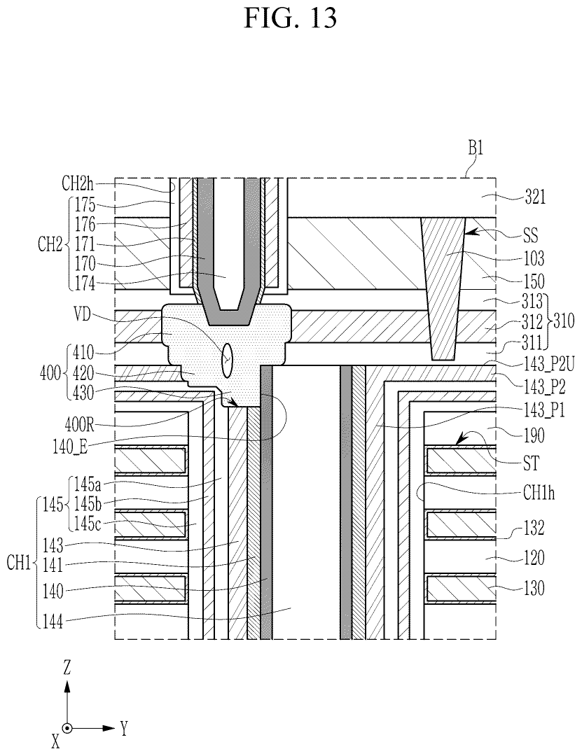

In an embodiment, the second ferroelectric layer 173 may include the same material as the first ferroelectric layer 143. For example, the second ferroelectric layer 173 may include or may be formed of a ferroelectric material. Since the description of the second ferroelectric layer 173 is substantially the same as the description of the first ferroelectric layer 143, it will be omitted. However, it is not limited to this, and the second ferroelectric layer 173 may include or may be formed of a different material from the first ferroelectric layer 143. This will be described later with reference to FIG. 13. The second insulation layer 175 may surround the second ferroelectric layer 173. For example, the second insulation layer 175 may cover an external surface and a bottom surface of the second ferroelectric layer 173. The second insulation layer 175 may be extended to have a conformal shape along the inner sidewall of the second channel hole CH2h. The second insulation layer 175 may be disposed to cover the inner sidewall and the bottom surface of the second channel hole CH2h. The second insulation layer 175 may be disposed between the selection gate electrode 150 and the second ferroelectric layer 173 and between the first upper insulation layer 321 and the second ferroelectric layer 173. The second insulation layer 175 may be disposed between the second ferroelectric layer 173 and the gate electrode 130.

In FIG. 4, the second insulation layer 175 is illustrated as a single layer, but this is not restrictive thereto. For example, the second insulation layer 175 may be formed of multiple layers. In some embodiments, the second insulation layer 175 may have or may be formed of the same structure or include the same material as the first insulation layer 145.

The contact pad 400 may penetrate the insulation pattern 310 and may be disposed between the first channel structure CH1 and the second channel structure CH2.

The contact pad 400 may penetrate at least a part of the third insulation pattern 313 and may penetrate the second insulation pattern 312 and the first insulation pattern 311. That is, the contact pad 400 may penetrate at least a part of the insulation pattern 310 and thus may be disposed between the first channel structure CH1 and the second channel structure CH2. The contact pad 400 may be electrically connected to the first channel structure CH1 and the second channel structure CH2. For example, the contact pad 400 may be electrically connected to the second channel layer 170 and the first channel layer 140.

Further referring to FIG. 5, the contact pad 400 may overlap at least a part of the first channel structure CH1 in the third direction (Z direction). For example, a part of the contact pad 400 may overlap the first channel structure CH1 in the third direction (Z direction), and a part of the remaining portion of the contact pad 400 may overlap the stacking structure ST in the third direction (Z direction). For example, as shown in FIG. 5, on a plane, a center of the contact pad 400 is spaced apart from a center CC1 of the first channel structure CH1 in the second direction (Y direction), and the contact pad 400 may overlap a part of the first channel structure CH1 in the third direction (Z direction). However, this is not restrictive thereto, and the center of the contact pad 400 may be disposed in a different direction from the center CC1 of the first channel structure CH1.

In addition, the contact pad 400 may overlap at least a part of the second channel structure CH2 in the third direction (Z direction). For example, the contact pad 400 may fully overlap the second channel structure CH2 in the third direction (Z direction). The contact pad 400 may overlap the second channel layer 170 in the third direction (Z direction).

In an embodiment, the contact pad 400 may fill a contact pad recess 400R. In this case, a bottom surface of the contact pad recess 400R may be defined by the vertical portion 143_P1 of the first ferroelectric layer 143, the first channel insulation layer 141, and the first insulation layer 145. An inner sidewall of the contact pad recess 400R may be defined by the insulation pattern 310, the horizontal portion 143_P2 of the first ferroelectric layer 143, and the exterior side 140_E of the first channel layer 140.

In an embodiment, a void VD may be disposed in the contact pad 400. The void VD may be defined by the contact pad 400. That is, the void VD may be surrounded by the contact pad 400. The void VD may overlap the second channel structure CH2 in the third direction (Z direction), but this is not restrictive thereto. In some embodiments, the void VD may correspond to an air gap. The term “air” as discussed herein, may refer to atmospheric air, or other gases that may be present during the manufacturing process.

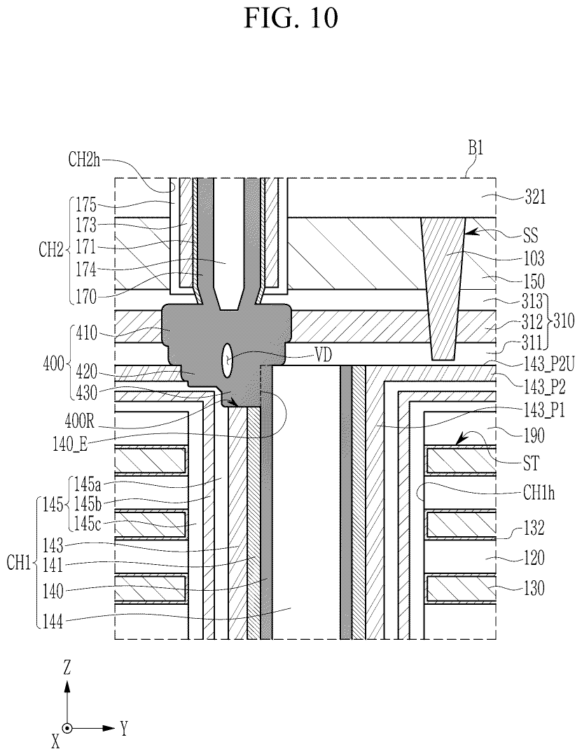

The contact pad 400 may include or may be formed of a semiconductor material. For example, the contact pad 400 may include or may be formed of a semiconductor material such as polycrystalline silicon. In some embodiments, the contact pad 400 may be doped with an N-type impurity, but this is not restrictive thereto. In an embodiment, the contact pad 400 may include a different material than the second channel layer 170. However, this is not restrictive thereto, and the contact pad 400 may be formed of the same material as the second channel layer 170. This will be described later with reference to FIG. 10.

In an embodiment, the contact pad 400 may include a first portion 410 penetrating the insulation pattern 310, a second portion 420 penetrating the horizontal portion 143_P2 of the first ferroelectric layer 143, and a third portion 430 protruded from a bottom surface of the second portion 420.

The first portion 410 of the contact pad 400 may penetrate at least a part of the insulation pattern 310. For example, the first portion 410 may penetrate the first insulation pattern 311 and the second insulation pattern 312, and may penetrate at least a part of the third insulation pattern 313. The first portion 410 may be disposed on the first channel structure CH1. The first portion 410 may be electrically connected to the second channel structure CH2.

In an embodiment, at least a part of the first portion 410 may overlap the first channel structure CH1 in the third direction (Z direction). For example, as shown in FIG. 5, on a plane, a center of the first portion 410 may be disposed at a distance from the center CC1 of the first channel structure CH1 in the second direction (Y direction). In this case, at least a part of the first portion 410 may overlap the first channel structure CH1 in the third direction (Z direction). However, this is not restrictive thereto. In some embodiments, the center of the first portion 410 may be disposed in a different direction from the center CC1 of the first channel structure CH1.

In addition, as shown in FIG. 4, on a cross-section formed of the second direction (Y direction) and the third direction (Z direction), the first portion 410 may extend from an upper portion of the second portion 420. For example, the first portion 410 may extend beyond opposite sides of the second portion 420 and may be disposed above the horizontal portion 143_P2 of the first ferroelectric layer 143 and the first channel structure CH1. In other words, one side of the first portion 410 may be disposed on the upper surface of the first channel structure CH1, and the other portion of the first portion 410 may be disposed on the upper surface 143_P2U of the horizontal portion 143_P2. For example, one side portion of the first portion 410 may be disposed on the upper surface of the first channel layer 140 and the upper surface of the first core insulation layer 144.

In an embodiment, the first portion 410 may have a circular shape in a plane. The first portion 410 may overlap at least a part of the second channel structure CH2 in the third direction (Z direction). For example, the first portion 410 may completely overlap the second channel structure CH2 in the third direction (Z direction). For example, the first portion 410 may overlap the second channel layer 170 in the third direction (Z direction).

In an embodiment, the first portion 410 may contact the first channel layer 140. For example, the first portion 410 may contact the upper surface of the first channel layer 140. The first portion 410 may overlap the first channel layer 140 in the third direction (Z direction). In addition, the first portion 410 may be in contact with the second channel layer 170. The first portion 410 may overlap the second channel layer 170. For example, the second channel layer 170 may completely overlap the first portion 410 in the third direction (Z direction).

The upper surface of the first portion 410 may be disposed closer to the selection gate electrode 150 than the upper surface of the second insulation pattern 312. That is, the upper surface of the first portion 410 may be disposed at a higher level than the upper surface of the second insulation pattern 312. An upper surface of the first portion 410 may be disposed farther from the upper surface of the substrate 101 than the upper surface of the second insulation pattern 312. In addition, the bottom surface of the first portion 410 may be disposed at substantially the same level as the upper surface 143_P2U of the horizontal portion 143_P2.

The second portion 420 of the contact pad 400 may protrude toward the substrate 101 from the bottom surface of the first portion 410. The second portion 420 may penetrate the horizontal portion 143_P2 of the first ferroelectric layer 143. The second portion 420 may be disposed between the first portion 410 and the third portion 430.

In an embodiment, the second portion 420 may penetrate at least a part of the first insulation layer 145. For example, as shown in FIG. 4, the second portion 420 may penetrate at least a part of the first blocking layer 145a. That is, the second portion 420 may be partially buried within the first insulation layer 145. Accordingly, the second portion 420 may overlap the first insulation layer 145 in the horizontal direction (first direction (X direction) and/or second direction (Y direction)). That is, the bottom surface of the second portion 420 may be disposed closer to the upper surface of the substrate 101 than the upper surface of the first insulation layer 145. That is, the bottom surface of the second portion 420 may be disposed at a lower level than the upper surface of the first insulation layer 145. In other words, the bottom surface of the second portion 420 may be disposed at a lower level than the bottom surface of the horizontal portion 143_P2 of the first ferroelectric layer 143.

In FIG. 4, it is illustrated that the second portion 420 penetrates at least a part of the first blocking layer 145a, but it is not limited thereto. For example, the second portion 420 may penetrate the first blocking layer 145a and contact the charge inflow layer 145b. This will be described later with reference to FIG. 11.

In an embodiment, the second portion 420 may be disposed on the exterior side 140E of the first channel layer 140. For example, the second portion 420 may be disposed between the horizontal portion 143_P2 of the first ferroelectric layer 143 and the first channel layer 140. The second portion 420 may overlap the horizontal portion 143_P2 of the first ferroelectric layer 143 and the first channel layer 140 in the horizontal direction (i.e., first direction (X direction) and/or second direction (Y direction)). A side surface of the second portion 420 may contact the exterior side 140E of the first channel layer 140. Accordingly, the second portion 420 may be electrically connected to the first channel layer 140.

In an embodiment, at least a part of the second portion 420 may overlap the first channel structure CH1 in the third direction (Z direction). For example, as shown in FIG. 5, on a plane, a center of the second portion 420 may be disposed apart from the center CC1 of the first channel structure CH1 in the second direction (Y direction). In this case, at least a part of the second portion 420 may overlap the first channel structure CH1 in the third direction (Z direction). However, this is not restrictive thereto, and the center of the second portion 420 may be disposed in a different direction from the center CC1 of the first channel structure CH1.

In an embodiment, the second portion 420 may have a circular shape in a plane. The second portion 420 may overlap at least a part of the second channel structure CH2 in the third direction (Z direction). For example, the second portion 420 may completely overlap the second channel structure CH2 in the third direction (Z direction). For example, the second portion 420 may overlap the second channel layer 170 in the third direction (Z direction). In an embodiment, the second portion 420 may overlap the second channel layer 170. In addition, the second portion 420 may overlap the first portion 410 in the third direction (Z direction).

In an embodiment, the upper surface of the second portion 420 may be disposed at substantially the same distance as the upper surface of the substrate 101 from the upper surface 143_P2U of the horizontal portion 143_P2. That is, the upper surface of the second portion 420 may be disposed at substantially the same level as the upper surface 143_P2U of the horizontal portion 143_P2. However, this is not restrictive thereto, and the upper surface of the second portion 420 may be disposed at a level higher or lower than the upper surface 143_P2U of the horizontal portion 143_P2.

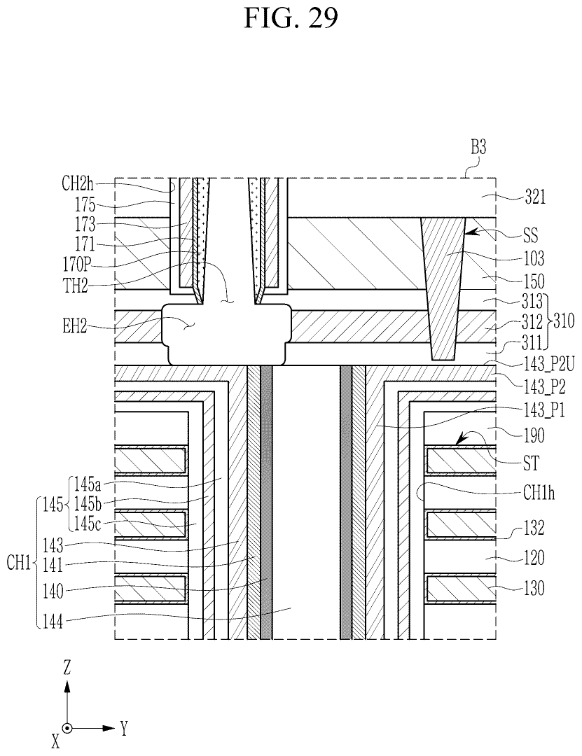

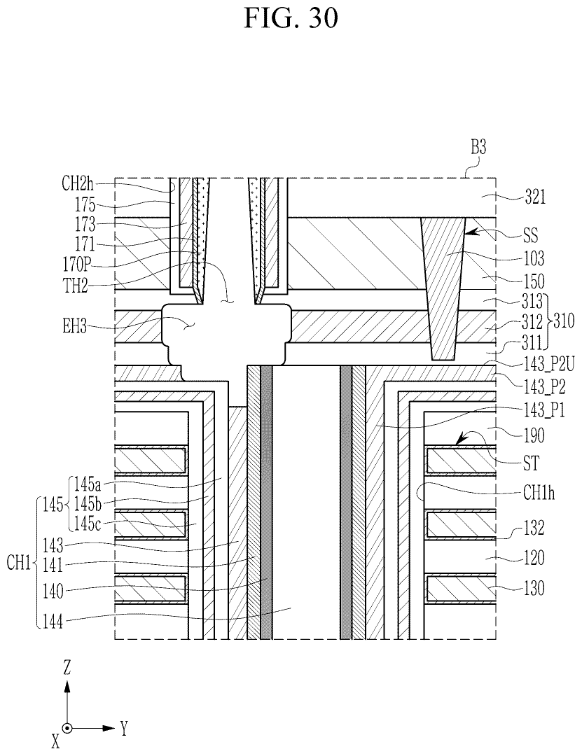

In an embodiment, a width of the second portion 420 in the second direction (Y direction) may be smaller than a width of the first portion 410 in the second direction (Y direction). In an embodiment, a maximum width of the second portion 420 in the second direction (Y direction) may be smaller than a maximum width of the first portion 410 in the second direction (Y direction). This may be due to forming a third expansion hole EH3 (refer to FIG. 30) by removing a part of the first ferroelectric layer 143 exposed by a second expansion hole EH2 (refer to FIG. 29) penetrating the insulation pattern 310 after forming the second expansion hole EH2, and the process characteristic of forming the contact pad 400 within a space where the first ferroelectric layer 143 is removed. For example, such a difference between the width of the second portion 420 and the width of the first portion 410 may be attributed to the following process integration: 1) forming the second expansion hole EH2 penetrating the insulation pattern 310; 2) forming the third expansion hole EH3 (refer to FIG. 30) by removing the part of the first ferroelectric layer 143 that is exposed by the second expansion hole EH2 (refer to FIG. 29); and forming the contact pad 400 within the third expansion hole EH3 where the first ferroelectric layer 143 is removed. However, this is not restrictive thereto, and a width of the second portion 420 in the first direction (X direction) may be smaller than or equal to a width of the first portion 410 in the first direction (X direction).

The third portion 430 of the contact pad 400 may protrude toward the substrate 101 from the bottom surface of the second portion 420.

The third portion 430 may be disposed on the first channel structure CH1. For example, the third portion 430 may be disposed on the first ferroelectric layer 143 and the first channel insulation layer 141. The third portion 430 may overlap the first channel structure CH1 in the third direction (Z direction). In addition, the third portion 430 may overlap the first insulation layer 145 in the third direction (Z direction). For example, the third portion 430 may overlap the first blocking layer 145a in the third direction (Z direction). This may be due to the process characteristic in which, in the process of forming the contact pad recess 400R, the first blocking layer 145a is etched together in the process of etching the first channel insulation layer 141 to expose the first channel layer 140. For example, the arrangement of the third portion 430 as described above may be attributed to the following process integration; during the formation of the contact pad recess 400R, the first blocking layer 145a is etched simultaneously with the first channel insulation layer 141, thereby exposing the first channel layer 140.

In an embodiment, the third portion 430 may overlap the second portion 420 in the third direction (Z direction). For example, at least a part of the second portion 420 may overlap the third portion 430 in the third direction (Z direction), and a part of the remaining of the second portion 420 may overlap the first insulation layer 145 in the third direction (Z direction). In addition, the third portion 430 may overlap the first portion 410 in the third direction (Z direction). For example, at least a part of the first portion 410 overlaps the third portion 430 in the third direction (Z direction), and a part of the remaining portion of the first portion 410 may overlap the second portion 420, the first insulation layer 145, and the stacking structure ST in the third direction (Z direction).

In an embodiment, the third portion 430 may be disposed on the exterior side 140E of the first channel layer 140. For example, the third portion 430 may be disposed between the first insulation layer 145 and the first channel layer 140. The third portion 430 may overlap the first insulation layer 145 and the first channel layer 140 in the horizontal direction (first direction (X direction) and/or second direction (Y direction)). A side surface of the third portion 430 may contact the exterior side 140E of the first channel layer 140. Accordingly, the third portion 430 may be electrically connected to the first channel layer 140.

The third portion 430 may extend along a circumferential direction of the first channel structure CH1. For example, as shown in FIG. 5, on a plane, the third portion 430 may extend along the circumferential direction of the first channel structure CH1 on the exterior side 140E of the first channel layer 140.

The third portion 430 may have a constant width along the circumferential direction of the first channel structure CH1. For example, a second width W2 along a diameter direction from the center CC1 of the first channel structure CH1 of the third portion 430 may be substantially the same along the circumferential direction of the first channel structure CH1. In this case, the second width W2 along the diameter direction from the center CC1 of the first channel structure CH1 of the third portion 430 may be greater than a first width W1 along the diameter direction from the center CC1 of the first channel structure CH1 of the first ferroelectric layer 143. This may be due to the process characteristic of etching a portion of the first ferroelectric layer 143, etching the exposed first channel insulation layer 141 and first blocking layer 145a, and forming the third portion 430 within the etched space. Such a difference between the first and second widths W1 and W2 in a radial direction may be attributed to the following process integration: etching the portion of the first ferroelectric layer 143, etching the exposed first channel insulation layer 141 and first blocking layer 145a, and forming the third portion 430 within the etched space.

In an embodiment, the second width W2 of the third portion 430 in the second direction (Y direction) may be greater than the first width W1 of the first ferroelectric layer 143 in the second direction (Y direction). In addition, the second width W2 of the third portion 430 along the second direction (Y direction) may be smaller than the width of the second portion 420 along the second direction (Y direction). Accordingly, the second width W2 of the third portion 430 along the second direction (Y direction) may be smaller than the width of the first portion 410 along the second direction (Y direction). However, this is not restrictive thereto, and the width of the third portion 430 in the first direction (X direction) may be larger than the width of the first ferroelectric layer 143 in the first direction (X direction). In addition, the width of the third portion 430 along the first direction (X direction) may be smaller than the width of the second portion 420 along the first direction (X direction).

In an embodiment, the third portion 430 may have a constant width depending on the aspect ratio. That is, the second width W2 along the diameter direction from the center CC1 of the first channel structure CH1 of the third portion 430 may be substantially the same depending on the aspect ratio. For example, in case that a space in which the third portion 430 is disposed has a small aspect ratio, the entirety of the third portion 430 may have a constant width. However, it is not limited to this. In some embodiments, the third portion 430 may have an inclined side surface, and the third portion 430 may have a decreasing width as it approaches the substrate 101 depending on the aspect ratio (e.g., in case that a space in which the third portion 430 is disposed has a high aspect ratio).

The bottom surface of the third portion 430 may be disposed closer to the stacking structure ST than the bottom surface of the insulation pattern 310. That is, a distance from the upper surface of the stacking structure ST to the bottom surface of the insulation pattern 310 may be greater than a distance from the upper surface of the stacking structure ST to the bottom surface of the third portion 430. That is, the bottom surface of the third portion 430 may be disposed at a lower level than the bottom surface of the insulation pattern 310.

In an embodiment, the first portion 410 to the third portion 430 of the contact pad 400 may be integrally formed by the same process. Therefore, the first portion 410 to the third portion 430 that are integrally formed may include or may be formed of the same material. For example, the first portion 410 to the third portion 430 may include polycrystalline silicon doped with an N-type impurity. Therefore, a boundary between the first portion 410 and the second portion 420 and between the second portion 420 and the third portion 430 may not be recognized.

In the semiconductor device according to an embodiment, the third portion 430 and the second portion 420 of the contact pad 400 may contact the exterior side 140E of the first channel layer 140, and the first portion 410 of the contact pad 400 may contact the upper surface of the first channel layer 140. Accordingly, a contact area between the contact pad 400 and the first channel layer 140 may be increased, and even though at least a part of the second channel structure CH2 does not overlap the first channel structure CH1 in the third direction (Z direction), a contact area between the first channel layer 140 and the contact pad of 400 can be secured. Accordingly, reliability of the semiconductor device 100 can be secured.

Referring back to FIG. 3, the semiconductor device 100 according to an embodiment may further include an upper wire structure 180.

The upper wire structure 180 may be electrically connected to the first and second channel structures CH1 and CH2. The upper wire structure 180 may include studs 181, contact plugs 182, and an upper wire 183. The studs 181 may penetrate the second upper insulation layer 322 and contact the upper surface of each second channel structure CH2. The upper wire structure 180 may include a conductive material.

In FIG. 2, it is illustrated that a planar area of each stud 181 is smaller than a planar area of each second channel structure CH2, but this is for illustrative purposes only, and the planar area of each stud 181 may be substantially the same as or larger than the planar area of each second channel structure CH2.

The contact plugs 182 may pass through the third upper insulation layer 323 and may be connected to the studs 181. The upper wire 183 may be disposed above the contact plugs 182 and the third upper insulation layer 323. A part of the upper wire 183 may be bit lines BL (refer to FIG. 34) that contact the contact plugs 182. The bit lines BL may extend in the second direction (Y direction) as shown in FIG. 1 and FIG. 2. That is, the upper wire 183 may cross the upper separation region SS. The bit lines BL may be electrically connected to the second channel structure CH2 through the contact plugs 182.

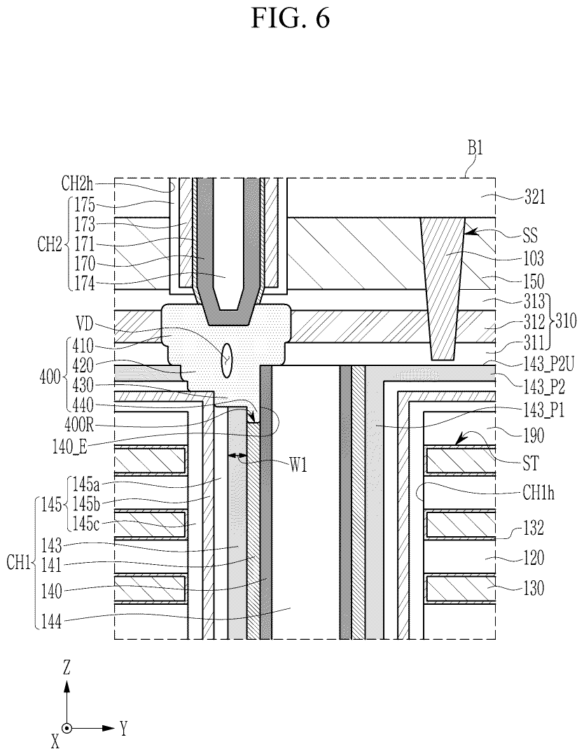

Hereinafter, a semiconductor device according to some embodiments will be described with further reference to FIG. 6 to FIG. 14.

FIG. 6 to FIG. 14 are cross-sectional views of a semiconductor device according to some embodiments, corresponding to the area B1 of FIG. 3.

The embodiment shown in FIG. 6 to FIG. 14 is almost the same as the embodiment shown in FIG. 1 to FIG. 5, and therefore description thereof will be omitted and differences will be mainly explained.

A memory cell region CELL of a semiconductor device 100 according to some embodiment may include a substrate 101, first and second horizontal conductive layers 102 and 104 disposed on the substrate 101, a stacking structure ST, a first channel structure CH1, an insulation pattern 310, a selection gate electrode 150, a second channel structure CH2, and a contact pad 400. Here, the stacking structure ST may include a plurality of gate electrodes 130 and interlayer insulation layers 120 that are alternately stacked.

Referring to FIG. 6, the contact pad 400 may further include a fourth portion 440 protruded toward the substrate 101 from a bottom surface of the third portion 430.

The fourth portion 440 may protrude toward the substrate 101 from the bottom surface of the third portion 430. The fourth portion 440 may be disposed on the first channel insulation layer 141. The fourth portion 440 may overlap the first channel insulation layer 141 in the third direction (Z direction).

In some embodiments, the fourth portion 440 may be disposed on the exterior side 140_E of the first channel layer 140. For example, the fourth portion 440 may be disposed between the first channel layer 140 and the first ferroelectric layer 143. The fourth portion 440 may overlap the first channel layer 140 in the horizontal direction (first direction (X direction) and/or second direction (Y direction)). The fourth portion 440 may contact the exterior side 140_E of the first channel layer 140. Accordingly, the fourth portion 440 may be electrically connected to the first channel layer 140.

In some embodiments, the fourth portion 440 may have a constant width. In some embodiments, the entirety of the fourth portion 440 may have a constant width. In other words, a width of the upper surface of the fourth portion 440 and a width of the bottom surface of the fourth portion 440 may be substantially the same as each other, but is not limited thereto. Here, the width of the fourth portion 440 may be a width according to the horizontal direction (first direction (X direction) and/or second direction (Y direction)).

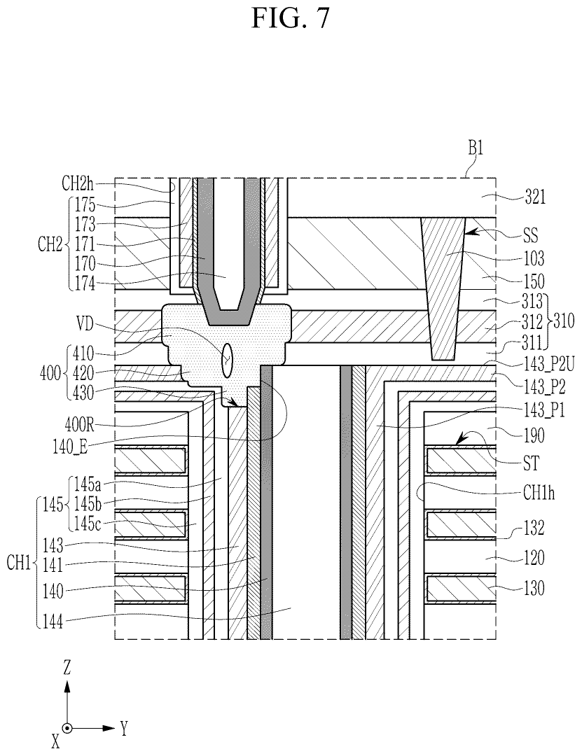

Referring to FIG. 7, the third portion 430 of the contact pad 400 according to some embodiments may be disposed between the first insulation layer 145 and the first channel insulation layer 141. For example, the third portion 430 may be protruded from the bottom surface of the second portion 420 into a space between the first insulation layer 145 and the first channel insulation layer 141 toward the substrate 101. Accordingly, the third portion 430 may be spaced apart from the exterior side of the first channel layer 140. The second portion 420 is in contact with the exterior side of the first channel layer 140, and thus the first channel layer 140 and the contact pad 400 may be electrically connected with each other.

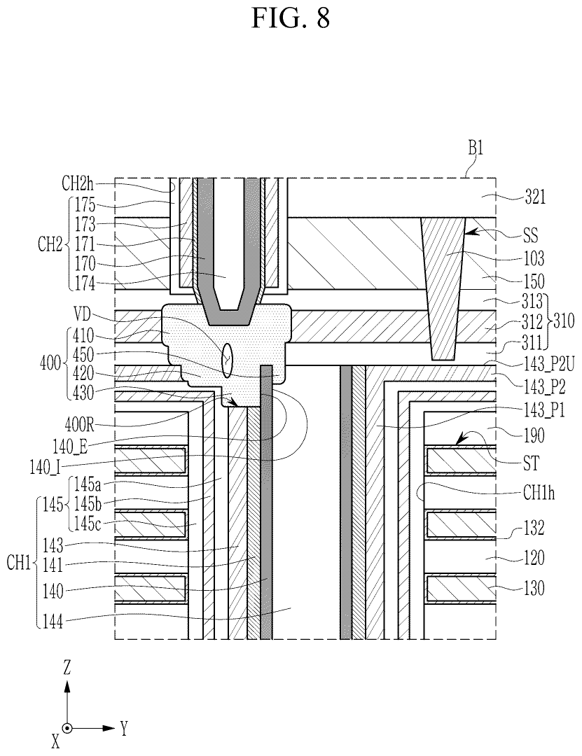

Referring to FIG. 8, the contact pad 400 of the semiconductor device 100 according to some embodiments may further include a fifth portion 450 that is disposed in a space between the first portion 410 and the first core insulation layer 144.

The fifth portion 450 may be protruded from the bottom surface of the first portion 410 toward the substrate 101. The fifth portion 450 may be disposed on the first core insulation layer 144. The fifth portion 450 may overlap the first core insulation layer 144 in the third direction (Z direction).

In an embodiment, the fifth portion 450 may be disposed on an inner surface 140_1 of the first channel layer 140. For example, the fifth portion 450 may be disposed between the first channel layer 140 and the first core insulation layer 144. The fifth portion 450 may overlap the first channel layer 140 in the horizontal direction (first direction (X direction) and/or second direction (Y direction)). The fifth portion 450 may be in contact with the inner surface 140_1 of the first channel layer 140. Accordingly, the fifth portion 450 may be electrically connected to the first channel layer 140.

In an embodiment, the fifth portion 450 may have a constant width. In an embodiment, the entirety of the fifth portion 450 may have a constant width. That is, a width of the upper surface of the fifth portion 450 and a width of the bottom surface of the fifth portion 450 may be substantially the same as each other. Here, the width of the fifth portion 450 may be a width according to the horizontal direction (first direction (X direction) and/or second direction (Y direction)).

In the case of the semiconductor device 100 according to an embodiment, the third portion 430 and the second portion 420 may be in contact with the exterior side 140E of the first channel layer 140, and the first portion 410 of the contact pad 400 may be in contact with the upper surface of the first channel layer 140. In addition, the fifth portion 450 may contact the inner surface 140_1 of the first channel layer 140. Accordingly, a contact area between contact pad 400 and first channel layer 140 can be increased, and even when at least a part of the second channel structure CH2 does not overlap the first channel structure CH1 in the third direction (Z direction), a contact area of the first channel layer 140 and the contact pad 400 can be secured. Accordingly, reliability of the semiconductor device 100 can be secured.

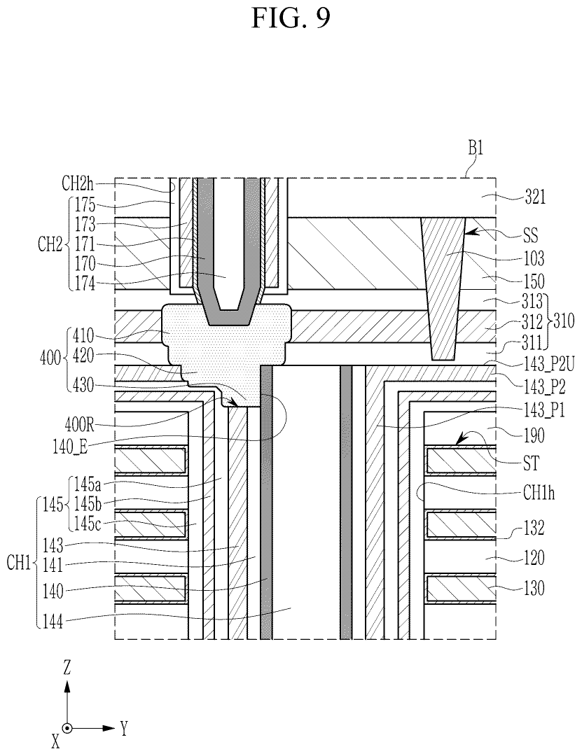

Referring to FIG. 9, a void VD may not be provided in the contact pad 400 of the semiconductor device 100 according to some embodiments. That is, the contact pad 400 may completely fill the contact pad recess 400R.

Referring to FIG. 10, the contact pad 400 of the semiconductor device 100 according to some embodiments may include or may be formed of the same material as the second channel layer 170. The contact pad 400 and the second channel layer 170 may include or may be formed of the same semiconductor material. For example, the contact pad 400 and the second channel layer 170 may include or may be formed of polycrystalline silicon. Here, the semiconductor material may be undoped with an impurity or may be doped with a P-type or N-type impurity. In some embodiments, the contact pad 400 and the second channel layer 170 may be integrally formed by the same process. Accordingly, a boundary between the contact pad 400 and the second channel layer 170 may not be recognized.

In some embodiments, the contact pad 400 may include or may be formed of the same material as the first channel layer 140, but this is not restrictive. In this case, the boundary between the contact pad 400 and the first channel layer 140 may not be recognized.

Referring to FIG. 11, a first insulation layer 145 of the semiconductor device 100 according to some embodiments may include a second blocking layer 145c and a charge inflow layer 145b that are sequentially disposed on an upper surface and a side surface of the stacking structure ST. The first insulation layer 145 of the semiconductor device 100 according to some embodiments may not include a first blocking layer disposed between the charge inflow layer 145b and the first ferroelectric layer 143.

The charge inflow layer 145b may be disposed between the first ferroelectric layer 143 and the stacking structure ST. For example, the charge inflow layer 145b may be disposed between the horizontal portion 143_P2 of the first ferroelectric layer 143 and the upper surface of the stacking structure ST and between the vertical portion 143_P1 of the first ferroelectric layer 143 and the side surface of the stacking structure ST. The charge inflow layer 145b may contact the first ferroelectric layer 143.

In some embodiments, the charge inflow layer 145b may include a material different from that of the first channel insulation layer 141 and the second blocking layer 145c. The charge inflow layer 145b may include a material having etch selectivity with respect to the first channel insulation layer 141 and the second blocking layer 145c. For example, the charge inflow layer 145b may include or may be formed of silicon nitride, but it is not limited thereto.

In some embodiments, when the charge inflow layer 145b is in contact with the first ferroelectric layer 143, the charge inflow layer 145b may be in contact with the contact pad 400. For example, when the charge inflow layer 145b contacts the horizontal portion 143_P2 and the vertical portion 143_P1 of the first ferroelectric layer 143, the charge inflow layer 145b may contact the second portion 420 and the third portion 430 of the contact pad 400. This is due to the process characteristic in which, in the process of forming the contact pad recess 400R, at least a part of the first ferroelectric layer 143 is removed, a part of the exposed first channel insulation layer 141 is removed, and the charge inflow layer 145b is not etched together. For example, such an arrangement of the charge inflow layer 145b may be attributed to the following process integration: in the process of forming the contact pad recess 400R, at least a part of the first ferroelectric layer 143 is removed, a part of the exposed first channel insulation layer 141 is removed without etching the charge inflow layer 145b.

Referring to FIG. 12, a first insulation layer 145 of the semiconductor device 100 according to some embodiments may be formed as a single layer. The first insulation layer 145 may be disposed between the first ferroelectric layer 143 and the stacking structure ST. For example, the first insulation layer 145 may be disposed between the horizontal portion 143_P2 of the first ferroelectric layer 143 and the upper surface of the stacking structure ST and between the vertical portion 143_P1 of the first ferroelectric layer 143 and the side surface of the stacking structure ST. The first insulation layer 145 may contact the first ferroelectric layer 143. The first insulation layer 145 may include or may be formed of an insulating material. The first insulation layer 145 may include or may be formed of the same material as the first channel insulation layer 141, but this is not restrictive thereto. For example, the first insulation layer 145 may include or may be formed of silicon oxide or silicon oxynitride, but is not limited thereto.

Referring to FIG. 13, a second channel structure CH2 of the semiconductor device 100 according to some embodiments may include a second core insulation layer 174, a second channel insulation layer 171 surrounding the second core insulation layer 174, a charge storage layer 176 surrounding the second channel insulation layer 171, and a second insulation layer 175 surrounding the charge storage layer 176. The second channel structure CH2 of FIG. 13 may include the charge storage layer 176 instead of the second ferroelectric layer 173 of FIG. 4.

The second core insulation layer 174 is provided in a central region of second channel structure CH2, and the second channel layer 170 may surround a sidewall of the second core insulation layer 174. In addition, the second channel insulation layer 171 may surround the second channel layer 170.

In some embodiments, the charge storage layer 176 may surround at least a part of the second channel insulation layer 171. The charge storage layer 176 may be disposed between the selection gate electrode 150 and the second channel insulation layer 171 and between the first upper insulation layer 321 and the second channel insulation layer 171. The charge storage layer 176 may be disposed between the second channel insulation layer 171 and the selection gate electrode 150. The charge storage layer 176 may include an insulating material. The charge storage layer 176 may include a different material from the first ferroelectric layer 143. For example, the charge storage layer 176 may include silicon nitride, but this is not restrictive thereto. The second insulation layer 175 may surround the charge storage layer 176. For example, the second insulation layer 175 may cover an exterior surface and a bottom surface of the charge storage layer 176.

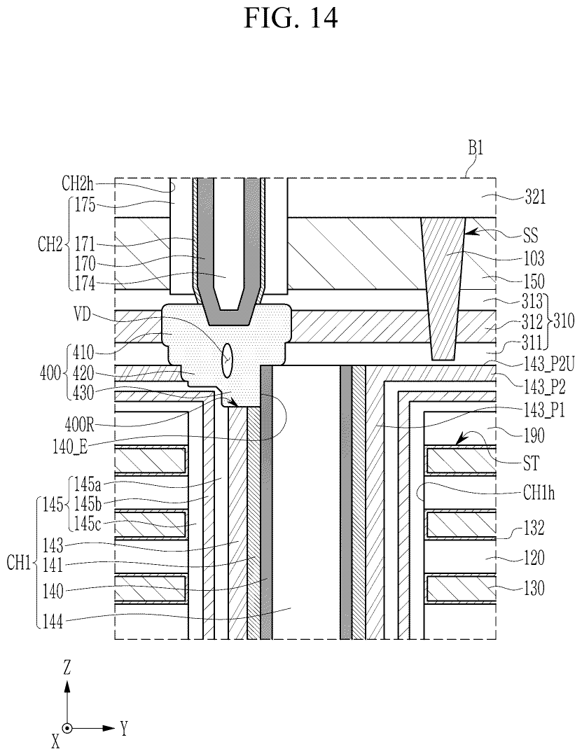

Referring to FIG. 14, the second channel structure CH2 of the semiconductor device 100 according to some embodiment may include a second core insulation layer 174, a second channel insulation layer 171 surrounding the second core insulation layer 174, and a second insulation layer 175 surrounding the second channel insulation layer 171. The second ferroelectric layer 173 of FIG. 4 is omitted.

The second insulation layer 175 may be disposed between the selection gate electrode 150 and the second channel insulation layer 171. The second insulation layer 175 may surround the second channel insulation layer 171. The second insulation layer 175 may be in contact with the second channel insulation layer 171. The second insulation layer 175 may be extended to have a conformal shape along the inner sidewall of the second channel hole CH2h. The second insulation layer 175 may be disposed to cover the inner sidewall of the second channel hole CH2h. The second insulation layer 175 may be disposed between the selection gate electrode 150 and the second channel insulation layer 171 and between the first upper insulation layer 321 and the second channel insulation layer 171. The second insulation layer 175 may include or may be formed of silicon oxide, silicon nitride, silicon nitride, or a combination thereof, but this is not restrictive.

In some embodiments, the second channel structure CH2 includes the second channel insulation layer 171 and the second insulation layer 175, but this is not restrictive. For example, the second channel structure CH2 may not include the second channel insulation layer 171. In this case, the second insulation layer 175 may contact the selection gate electrode 150 and the second channel layer 170.

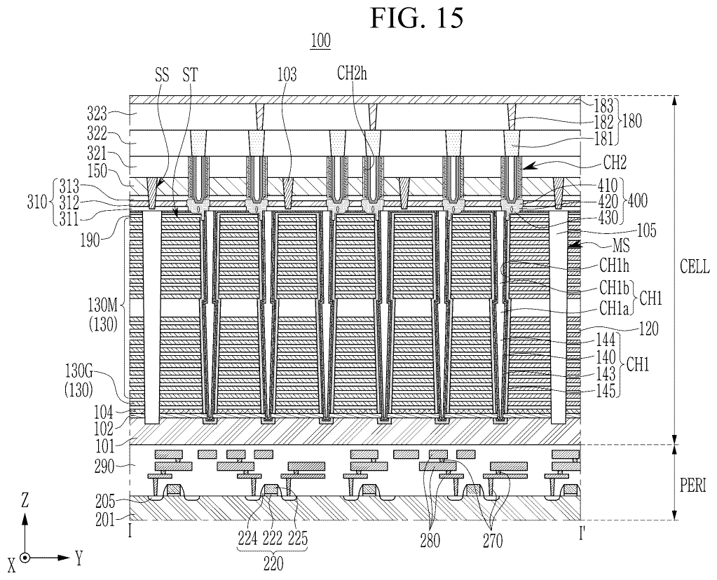

Hereinafter, referring to FIG. 15, a semiconductor device according to an embodiment will be described. In the following embodiments, the same components as the previously described embodiments will be referred to by the same reference numerals, redundant descriptions will be omitted or simplified, and differences will be mainly explained.

FIG. 15 is a cross-sectional view of a semiconductor device according to some embodiments. FIG. 15 is a cross-sectional view of FIG. 1, taken along the line I-I′.

Referring to FIG. 15, in a semiconductor device 100i, a stacking structure of a plurality of gate electrodes 130 is formed of vertically stacked lower and upper stacking structures, and a first channel structure CH1 may be formed of vertically stacked lower and upper channel structures CH1a and CH1b. Such a structure of the first channel structure CH1 may be introduced to stably form the first channel structure CH1 in a case where a number of the plurality of gate electrodes 130 stacked on each other is relatively high. In some embodiments, the number of the plurality of gate electrodes 130 stacked on each other may be 430 or more. In some embodiments the number of the plurality of gate electrodes 130 stacked on each other may be 1,000, Depending on embodiments, the number of stacked first channel structures may vary.

The first channel structure CH1 may have a form in which the lower channel structure CH1a and the upper channel structure CH1b are connected with each other, and may have a bent portion due to a difference in width at a connection region between the lower channel structure CH1a and the upper channel structure CH1b. A first channel layer 140, a first channel insulation layer 141, a first ferroelectric layer 143, a first insulation layer 145, and a first core insulation layer 144 may be connected with each other between the lower channel structure CH1a and the upper channel structure CH1b.

An upper interlayer insulation layer with a relatively thick thickness may be placed on the top of the lower stacking structure. However, it is not limited to this, and the shape of the upper interlayer insulation layer may change in various embodiments.

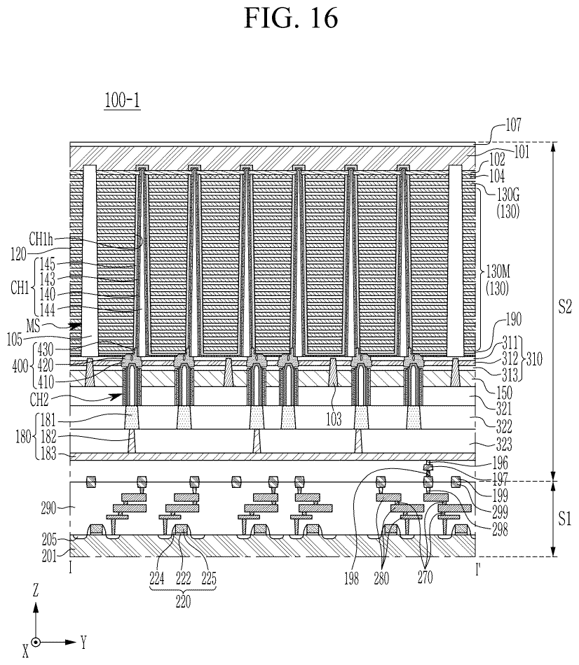

Hereinafter, referring to FIG. 16, a semiconductor device according to some embodiments will be described. In the following embodiments, the same components as the previously described embodiments will be referred to by the same reference numerals, redundant descriptions will be omitted or simplified, and differences will be mainly explained.

FIG. 16 is a cross-sectional view of a semiconductor device according to some embodiments. FIG. 16 is a cross-sectional view of FIG. 1, taken along the line I-I′.

According to an embodiment shown in FIG. 16, a semiconductor device 100_1 may include a first structure S1 and a second structure S2 bonded by a wafer bonding method.

The first structure S1 of FIG. 16 may correspond to the peripheral circuit region PERI described above with reference to FIG. 3. However, the first structure S1 may further include first bonding vias 298 and first bonding pads 299, which are bonding structures.

Specifically, the first bonding vias 298 may be disposed above the uppermost circuit wire lines 280 and connected to the circuit wire lines 280. At least a portion of the first bonding pads 299 may be disposed on the first bonding vias 298 and may be connected to the first bonding vias 298. The first bonding pads 299 may be connected to the second bonding pads 199 of the second structure S2. The first bonding pads 299 may provide an electrical connection path according to the bonding of the first structure S1 and the second structure S2, together with the second bonding pads 199. The first bonding vias 298 and the first bonding pads 299 may include or may be formed of a conductive material, for example, copper (Cu). However, this is not restrictive thereto.

Unless otherwise specified for the second structure S2, the contents described above with reference to FIG. 1 to FIG. 14 can be applied substantially the same except that the substrate 101 and the first channel structure CH1 of the second structure S2 are disposed on an upper side and the second channel structure CH2 is disposed on the lower side.

An upper wire structure of the second structure S2 may further include a conductive via 196 and a conductive line 197 connected to an upper wire 183. It is illustrated in FIG. 16 that a plurality of conductive lines 197 are disposed at the same level, but it is not limited to this, and in some embodiments, not as shown in FIG. 16, the conductive line 197 may include a plurality of conductive lines disposed at different levels.

In addition, the second structure S2 may further include second bonding vias 198 and second bonding pads 199, which are bonding structures. The second structure S2 may further include a protective layer 107 covering an upper surface of the substrate 101.

The second bonding vias 198 and the second bonding pads 199 may be disposed below the lowest conductive line 197. The second bonding vias 198 may be connected to the conductive line 197 and the second bonding pads 199, and the second bonding pads 199 may be connected to the first bonding pads 299 of the first structure S1. The second bonding vias 198 and the second bonding pads 199 may include or may be formed of a conductive material, for example, copper (Cu). However, this is not restrictive thereto.

The first structure S1 and the second structure S2 may be bonded by copper (Cu)-copper (Cu) bonding using the first bonding pads 299 and the second bonding pads 199. In addition to the copper (Cu)-copper (Cu) bonding, the first structure S1 and the second structure S2 may additionally be bonded by dielectric material-dielectric material bonding. The dielectric material-dielectric material bonding may form a part of each of the peripheral area insulation layer 290 and the cell region insulation layer 190, and may be bonding by dielectric layers surrounding each of the first bonding pads 299 and the second bonding pads 199. Accordingly, the first structure S1 and the second structure S2 may be bonded without a separate adhesive layer.

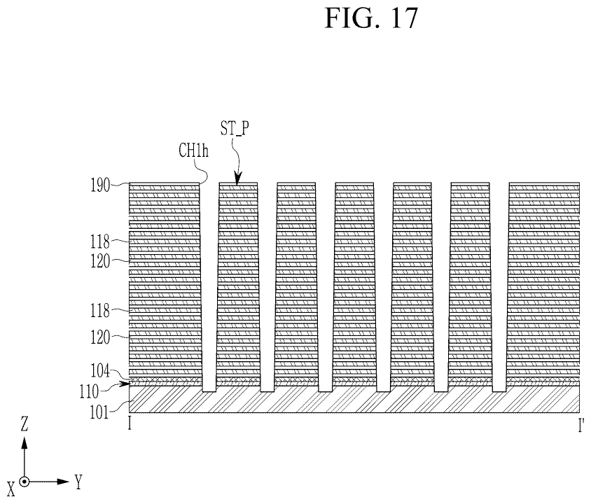

Hereinafter, referring to FIG. 17 to FIG. 33, a method of manufacturing a semiconductor device according to an embodiment will be described.

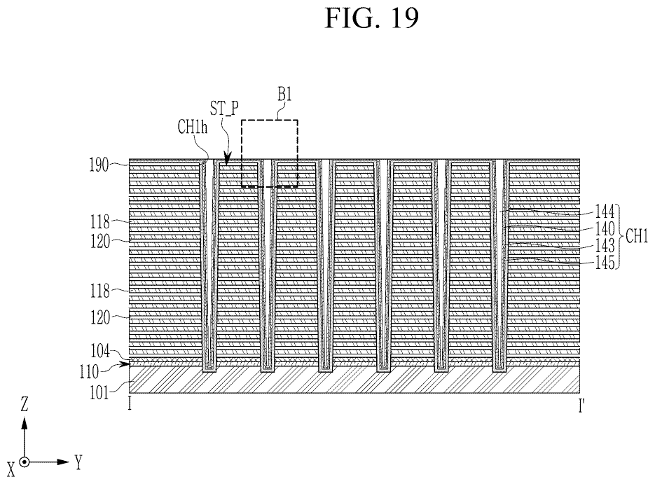

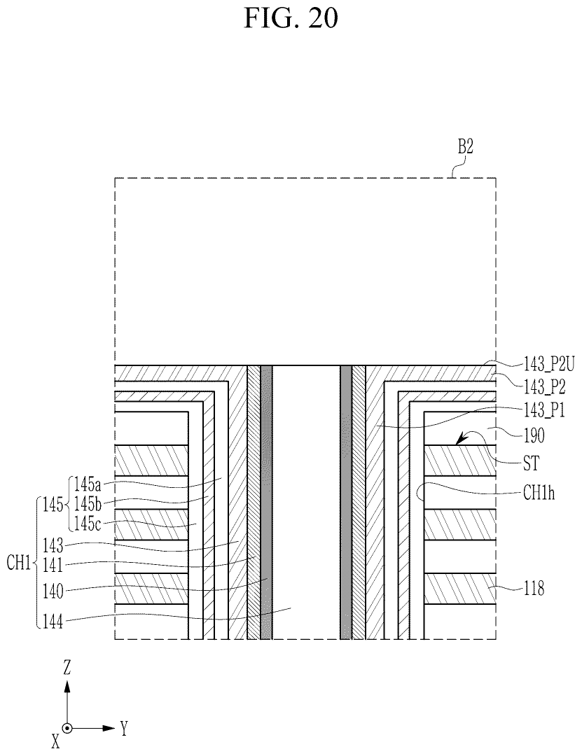

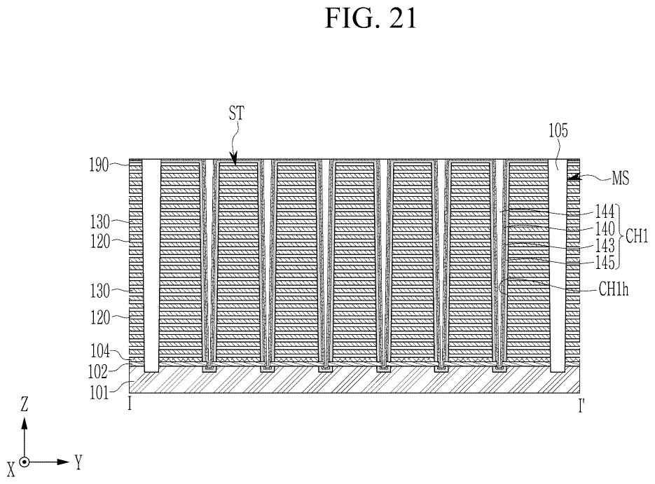

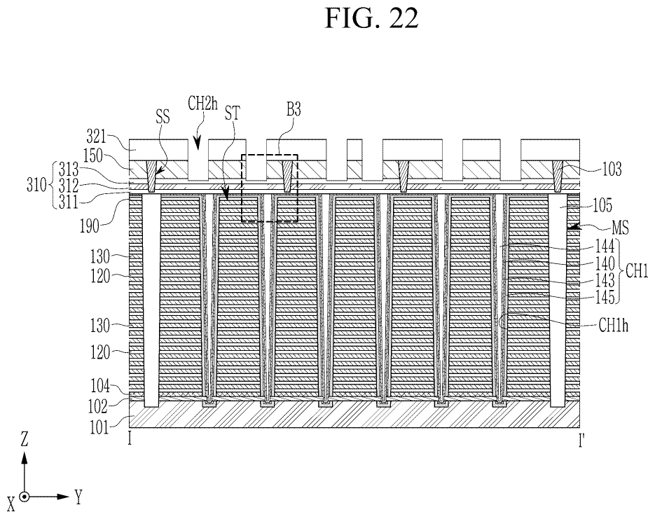

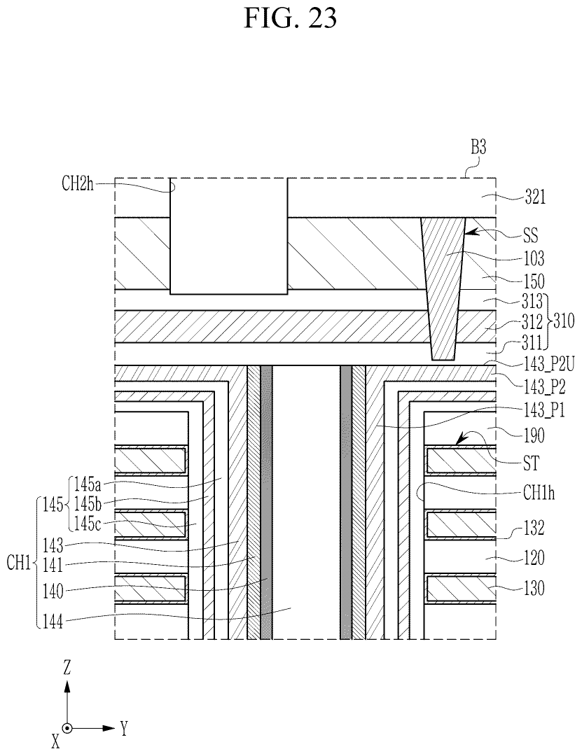

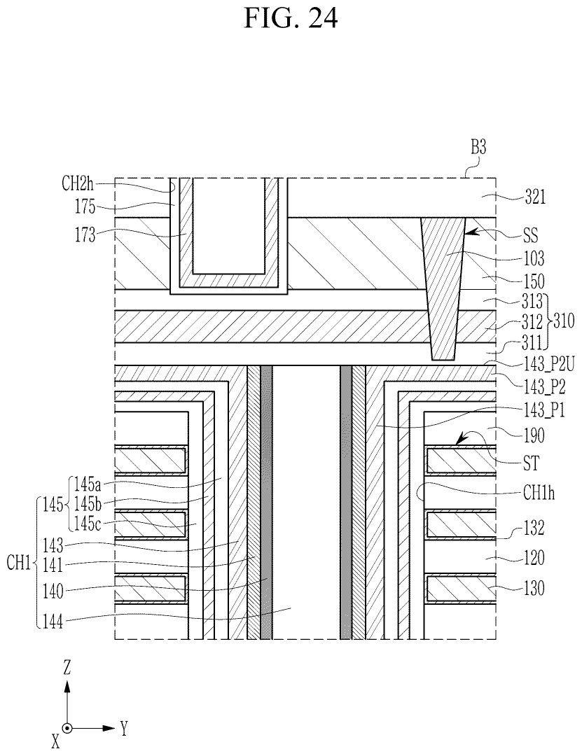

FIG. 17 to FIG. 19 are cross-sectional views of a method of manufacturing a semiconductor device according to some embodiments. FIG. 20 is an enlarged cross-sectional view of the area B2 of FIG. 19. FIG. 21 and FIG. 22 are cross-sectional views of a method of manufacturing a semiconductor device according to some embodiments. FIG. 23 is an enlarged cross-sectional view of the area B3 of FIG. 22. FIG. 24 to FIG. 33 show a method of manufacturing a semiconductor device according to some embodiments, and are cross-sectional views corresponding to the area B3 of FIG. 15. Hereinafter, the same configuration described previously will be referred to by the same reference numerals, redundant explanations will be omitted or simplified, and differences will be mainly explained.

Referring to FIG. 17, horizontal sacrificial layers 110 and a second horizontal conductive layer 104 are formed first on a substrate 101, and sacrificial insulation layers 118 and interlayer insulation layers 120 are alternately stacked such that a preliminary stacking structure ST_P can be formed.

Although it is not shown in FIG. 17, the horizontal sacrificial layers 110 may include first to third horizontal sacrificial layers formed sequentially on the substrate 101. In this case, the second horizontal sacrificial layer may contain different material than the first horizontal sacrificial layer and the third horizontal sacrificial layer. The horizontal sacrificial layers 110 may be layers that are replaced with the first horizontal conductive layer (refer to 102 in FIG. 21) through subsequent process. For example, the first and third horizontal sacrificial layers may be formed of the same material as the interlayer insulation layers 120, and the second horizontal sacrificial layer may be formed of the same material as the sacrificial insulation layers 118. A second horizontal conductive layer 104 may be formed on the horizontal sacrificial layers 110.

In addition, the sacrificial insulation layers 118 may be a layer that is partially replaced with first gate electrodes (refer to 130 in FIG. 21) through a subsequent process. The sacrificial insulation layers 118 may be formed of a different material than the interlayer insulation layers 120. The sacrificial insulation layers 118 may include a material with etch selectivity with respect to the interlayer insulation layers 120. For example, the interlayer insulation layer 120 may be formed of at least one of silicon oxide and silicon nitride, and the sacrificial insulation layers 118 may be formed of a material different from the interlayer insulation layer 120 selected from silicon, silicon oxide, silicon carbide, and silicon nitride. Thicknesses and the number of constituting films of the interlayer insulation layers 120 and the sacrificial insulation layers 118 may vary from those shown.

Subsequently, a first channel hole CH1h penetrating the preliminary stacking structure ST_P may be formed. Specifically, a cell region insulation layer 190 that covers the preliminary stacking structure ST_P consisting of the sacrificial insulation layers 118 and interlayer insulation layers 120 may be formed. Next, an opening corresponding to the first channel hole CH1h that penetrates the cell region insulation layer 190 and the preliminary stacking structure ST_P may be formed. The first channel hole CH1h may be formed by etching the sacrificial insulation layers 118 and the interlayer insulation layers 120 included in the preliminary stacking structure ST_P using a mask layer. Due to a height of the preliminary stacking structure ST_P, a sidewall of the first channel hole CH1h may not be vertical to an upper surface of the substrate 101. The first channel hole CH1h may extend into the substrate 101 by recessing a portion of the substrate 101.

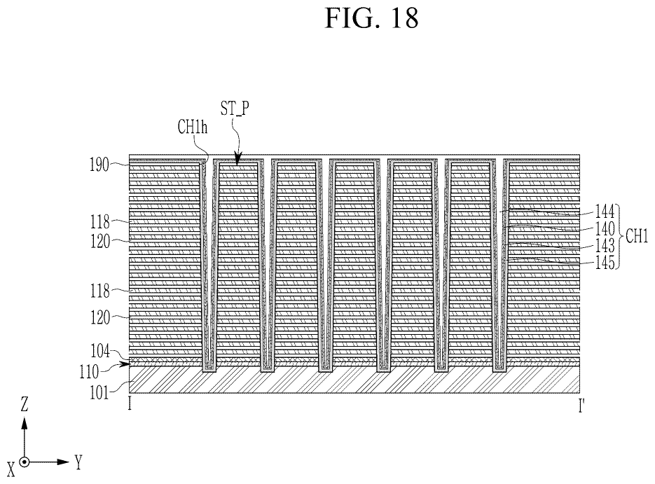

Referring to FIG. 18, the first channel structure CH1 may be formed in the first channel hole CH1h. Specifically, the first insulation layer 145, the first ferroelectric layer 143, the first channel insulation layer 141, the first channel layer 140, and the first core insulation layer 144 may be formed sequentially on an upper surface of the cell region insulation layer 190 and within the first channel hole CH1h. The first insulation layer 145, the first ferroelectric layer 143, the first channel insulation layer 141, and the first channel layer 140 may be formed to have a uniform thickness using an atomic layer deposition (ALD) process or a chemical vapor deposition (CVD) process. The first core insulation layer 144 is formed to fill the inside of the first channel structure CH1 and may be an insulating material.

Referring to FIG. 19 and FIG. 20, at least a part of the first channel structure CH1 may be planarized using a chemical-mechanical polishing (CMP) process. For example, the first core insulation layer 144, the first channel layer 140, and the first channel insulation layer 141 positioned on the upper surface of the cell region insulation layer 190 may be removed by using the CMP process. Accordingly, a portion of the first ferroelectric layer 143 disposed on the upper surface of the cell region insulation layer 190 may be exposed.

In an embodiment, the first ferroelectric layer 143 may include a vertical portion 143_P1 disposed in the first channel hole CH1h and a horizontal portion 143_P2 disposed on the upper surface of the cell region insulation layer 190. In addition, the first insulation layer 145 may include a portion disposed in the first channel hole CH1h and a portion disposed on the upper surface of the cell region insulation layer 190. In other words, the first insulation layer 145 may be disposed between the vertical portion 143_P1 of the first ferroelectric layer 143 and the cell region insulation layer 190 and between the horizontal portion 143_P2 of the first ferroelectric layer 143 and the preliminary stacking structure ST_P.

Referring to FIG. 21, a first horizontal conductive layer 102, a plurality of gate electrodes 130, and a separation insulation layer 105 may be formed.

First, openings penetrating the preliminary stacking structure ST_P may be formed in regions corresponding to separation regions MS, and the first horizontal conductive layer 102 and the plurality of gate electrodes 130 may be formed.

Specifically, a mask layer including an opening may be formed on the first channel structure CH1. The opening may be formed to penetrate the preliminary stacking structure ST_P consisting of the sacrificial insulation layers 118 and the interlayer insulation layers 120, the second horizontal conductive layer 104, and the horizontal sacrificial layers 110. The opening may be formed to extend in the third direction (Z direction). Accordingly, the preliminary stacking structure ST_P may be separated to form the stacking structures ST.

Next, the horizontal sacrificial layers 110 exposed by the opening may be removed. The horizontal sacrificial layers 110 may be removed, for example, by a dry etching process. In a process in which the horizontal sacrificial layers 110 are removed, parts of the first insulation layer 145, the first ferroelectric layer 143, and the first channel insulation layer 141 exposed in regions from which the horizontal sacrificial layers 110 are removed may also be removed. After that, the first horizontal conductive layer 102 may be formed in a space from which the horizontal sacrificial layers 110 are removed.

Next, the sacrificial insulation layer 118 exposed by the opening is removed to form tunnel portions, and a plurality of gate electrodes 130 may be formed by filling the tunnel portions with a conductive material. The tunnel portions may be formed, for example, through a dry etching process that selectively removes the sacrificial insulation layers 118 with respect to the interlayer insulation layers 120.

The conductive material that forms the plurality of gate electrodes 130 may include or may be formed of a metal, polycrystalline silicon, or a metal silicide material. In this case, before forming the plurality of gate electrodes 130, a dielectric layer with a conformal thickness may be deposited to form a gate dielectric layer (refer to 132 in FIG. 4).

Subsequently, a separation insulation layer 105 may be formed within the separation regions MS. A process of forming the separation insulation layer 105 may be formed by filling the openings with an insulating material and then performing a planarization process to remove the mask layer and the insulating material. The insulating material may include silicon oxide, silicon nitride, or silicon oxynitride. However, it is not limited to this, and in some embodiments, the openings may be filled with a conductive material along with the insulating material.

The planarization process may be performed such that an upper surface of the separation insulation layer 105 within the separation regions MS is disposed at substantially the same level as the upper surface of the first channel structure CH1.

Referring to FIG. 22 and FIG. 23, an insulation pattern 310, a selection gate electrode 150, and an upper separation layer 103 may be formed.

First to third insulation patterns 311 to 313 and the selection gate electrode 150 may be sequentially formed on the separation regions MS and the cell region insulation layer 190 through a deposition process. Subsequently, an upper separation layer 103 may be formed within the upper separation region SS, and a first upper insulation layer 321 may be formed through a deposition process.

The first insulation pattern 311 to the third insulation pattern 313 may extend in the first direction (X direction) and the second direction (Y direction). The first insulation pattern 311 to the third insulation pattern 313 may include an insulating material. For example, the first and third insulation patterns 313 may include a first insulating material, and the second insulation pattern 312 may include a second insulating material different from the first insulating material of the first and second insulation patterns 311 and 313. The second insulation pattern 312 may include a material having etch selectivity with respect to the first insulation pattern 311 and the third insulation pattern 313. In addition, the second insulation pattern 312 may include a material having etch selectivity with respect to the first channel structure CH1.

The selection gate electrode 150 may be formed by depositing a conductive material, for example, doped polycrystalline silicon. The selection gate electrode 150 may be formed to have a thickness greater than a thickness of each of the plurality of gate electrodes 130, but this is not limited thereto.

Next, trenches penetrating the selection gate electrode 150 and the insulation pattern 310 are formed to form a region corresponding to the upper separation region SS, and after depositing an insulating material within the trenches, a planarization process is performed to form an upper separation layer 103.

Subsequently, a second channel hole CH2h penetrating the first upper insulation layer 321 and the selection gate electrode 150 may be formed. Accordingly, the second channel hole CH2h may expose the insulation pattern 310. On a plane, the second channel hole CH2h may include portions overlapping and not-overlapping the first channel structure CH1. For example, the second channel hole CH2h may partially overlap the first channel structure CH1.

In the process of forming the second channel hole CH2h, a part of the insulation pattern 310 may be removed. For example, at least a part of the third insulation pattern 313 may be removed in the process of forming the second channel hole CH2h. In other words, the third insulation pattern 313 may include a portion recessed by the second channel hole CH2h, but it is not limited thereto. In some embodiments, the upper surface of the third insulation pattern 313 may be exposed without being recessed in the process of forming the second channel hole CH2h.

Referring to FIG. 24, a second insulation layer 175 and a second ferroelectric layer 173 may be formed sequentially within the second channel hole CH2h.

Specifically, deposition processes may be performed sequentially to form the second insulation layer 175 and the second ferroelectric layer 173 that conformally cover the upper surface of the first upper insulation layer 321, the inner sidewall and the bottom surface of the second channel hole CH2h.

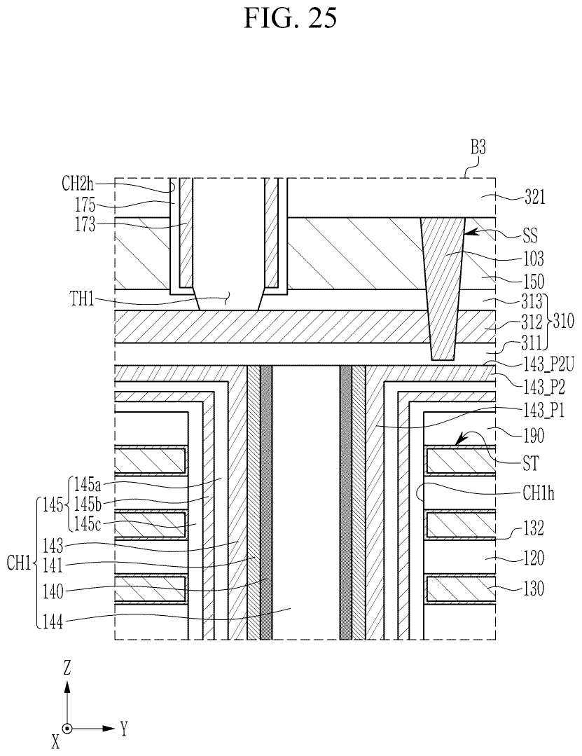

Referring to FIG. 25, a first through-hole TH1 that extends downward from a bottom surface of the second channel hole CH2h may be formed by partially etching the second ferroelectric layer 173, the second insulating layer 175, and the third insulation pattern 313. For example, the first through-hole TH1 may be formed such that the second insulation pattern 312 is exposed.

By performing an etch process on the resulting structure of FIG. 24, the second insulation layer 175 and the second ferroelectric layer 173 sequentially disposed on the bottom of the second channel hole CH2h, and the third insulation pattern 313 disposed on the bottom of the second channel hole CH2h may be removed to form the first through-hole TH1. Accordingly, the second insulation pattern 312 may be exposed through the first through-hole TH1.

In this case, as described above, the second insulation pattern 312 includes a material that has etch selectivity with respect to the third insulation pattern 313, and thus the second insulation pattern 312 may not be removed during the etch process performed on the third insulation pattern 313. However, this is not restrictive thereto, and while the etch process is in progress, a part of the second insulation pattern 312 may be removed together.

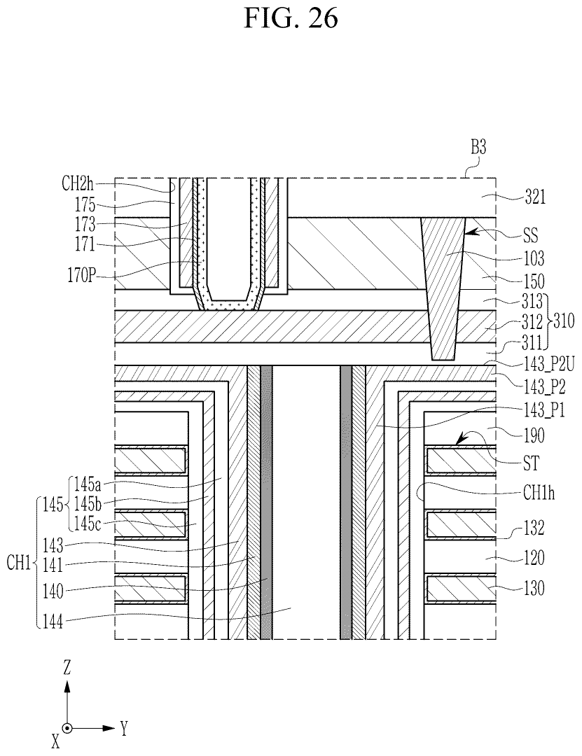

Referring to FIG. 26, a second channel insulation layer 171 and a preliminary channel layer 170P may be formed sequentially within the first through-hole TH1.

Specifically, a deposition process is performed sequentially to form the second channel insulation layer 171 and the preliminary channel layer 170P that conformally cover a side surface of the second ferroelectric layer 173, a side surface of the third insulation pattern 313, and an upper surface of the second insulation pattern 312. The side surface of the third insulation pattern 313 may be defined by the first through-hole TH1. The preliminary channel layer 170P may include or may be formed of amorphous silicon or polycrystalline silicon.

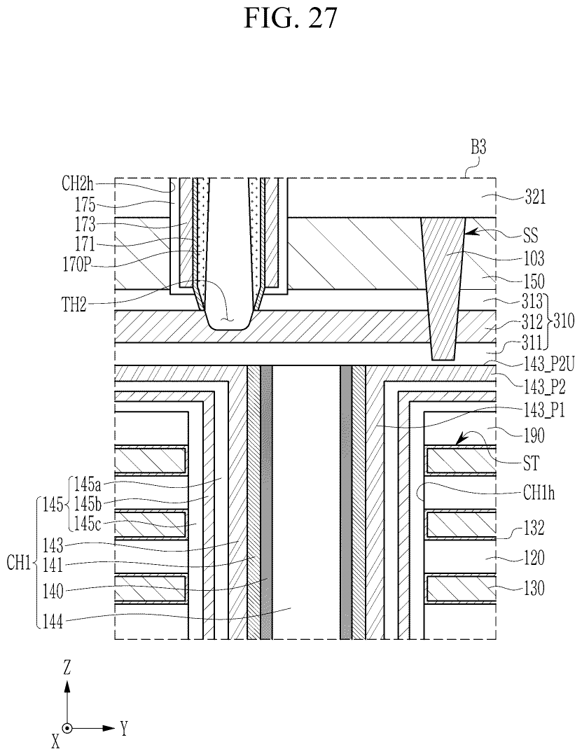

Referring to FIG. 27, a second through-hole TH2 extending below the bottom of the first through-hole TH1 may be formed.

The second through-hole TH2 may be formed by etching a bottom portion of the preliminary channel layer 170P, a bottom portion of the second channel insulation layer 171, and at least a part of the second insulation pattern 312. The etching process may be a dry etching process, but is not limited thereto. In some embodiments, the etching process may be an anisotropic etching process such as a reactive-ion etching process.

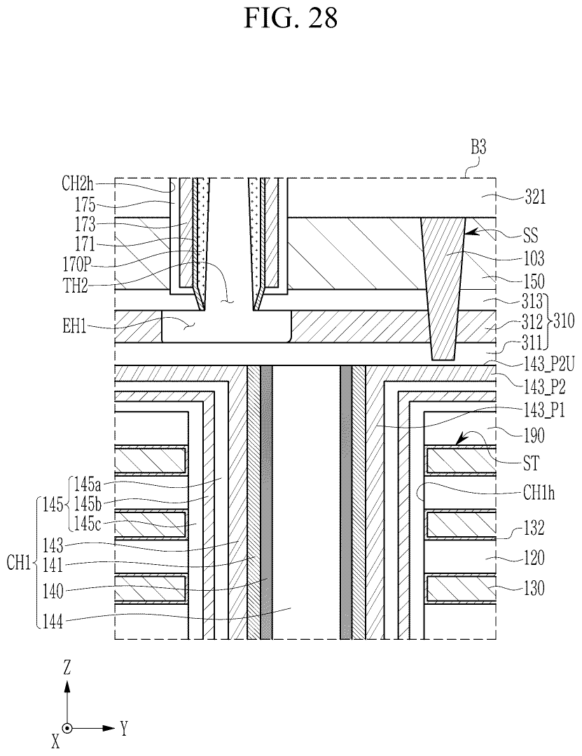

Referring to FIG. 28, a first expansion hole EH1 may be formed by etching the side surface of the second insulation pattern 312, exposed by the second through-hole TH2.

The first expansion hole EH1 may be extended in the horizontal direction (first direction (X direction) and/or second direction (Y direction)) within the second insulation pattern 312. For example, the first expansion hole EH1 may be formed to have a circular shape on a plane.

A process of forming the first expansion hole EH1 may be performed using a dry etching process. In this case, as described above, the second insulation pattern 312 may include a material having etch selectivity with respect to the first insulation pattern 311 and the third insulation pattern 313. Therefore, in the process of forming the first expansion hole EH1 by removing a portion of the second insulation pattern 312, the first insulation pattern 311 and the third insulation pattern 313 can be prevented from being etched.

Referring to FIG. 29, a second expansion hole EH2 may be formed by removing the first insulation pattern 311 exposed by the first expansion hole EH1.

A process of forming the second expansion hole EH2 may be carried out using a dry etching process, but is not limited thereto. Accordingly, the upper surface of the horizontal portion 143_P2 of the first ferroelectric layer 143, the upper surface of the first channel layer 140, and the upper surface of the first core insulation layer 144 may be exposed. In this case, in the process of removing the first insulation pattern 311, at least a part of the third insulation pattern 313 may be removed together.

In an embodiment, the second expansion hole EH2 may extend in the horizontal direction (first direction (X direction) and/or second direction (Y direction)) in the first insulation pattern 311. For example, the second expansion hole EH2 may be formed to have a circular shape on a plane.

Referring to FIG. 30, a third expansion hole EH3 may be formed by etching a part of the first ferroelectric layer 143 exposed by the second expansion hole EH2.

Specifically, a part of the first ferroelectric layer 143 exposed by the second expansion hole EH2 may be etched. A process for etching the first ferroelectric layer 143 may be carried out using dry etching, but is not limited thereto. The first ferroelectric layer 143 may include or may be formed of a material having etch selectivity with respect to the first insulation pattern 311 to the third insulation pattern 313, the first channel insulation layer 141, and the first insulation layer 145. Therefore, while a portion of the first ferroelectric layer 143 is etched, the first insulation pattern 311 to the third insulation pattern 313, the first channel insulation layer 141, and the first insulation layer 145 may not be etched. As the third expansion hole EH3 is formed, a side surface of the first channel insulation layer 141 and a side surface of the first insulation layer 145 may be exposed.

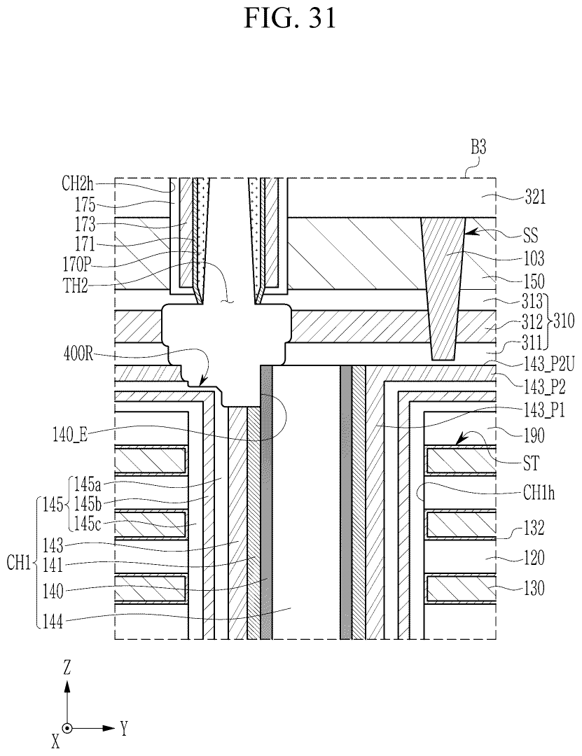

Referring to FIG. 31, a contact pad recess 400R may be formed by partially etching the first channel insulation layer 141 exposed by the third expansion hole EH3.

Specifically, a part of the first channel insulation layer 141 etched by the third expansion hole EH3 may be etched. A process for etching the first channel insulation layer 141 may be performed using dry etching, but is not limited thereto. The first channel insulation layer 141 may include a material having etch selectivity with respect to the first channel layer 140 and the first ferroelectric layer 143. Thus, while the first channel insulation layer 141 is partially etched, the first ferroelectric layer 143 may not be etched together.

In this case, while the first channel insulation layer 141 is partially etched, a part of a first insulation layer 145 adjacent to the first channel insulation layer 141 may be etched together. For example, while the first channel insulation layer 141 is partially etched, a part of a first blocking layer 145a adjacent to the first channel insulation layer 141 may be etched together. In an embodiment, a portion of the first blocking layer 145a is etched, but is not limited thereto, and the first blocking layer 145a may be etched to expose the charge inflow layer 145b.

Accordingly, a part of the first insulation layer 145 is etched such that the contact pad recess 400R can be formed. An exterior side of the first channel layer 140, a side surface of the first insulation layer 145, an upper surface of the first ferroelectric layer 143, and an upper surface of the first channel insulation layer 141 may be exposed by the contact pad recess 400R. Accordingly, in an embodiment, an upper surface of the first channel layer 140 may be exposed by the first expansion hole EH1, and the exterior side 140E of the first channel layer 140 may be exposed by the contact pad recess 400R. That is, an exposed area of the first channel layer 140 may be increased.

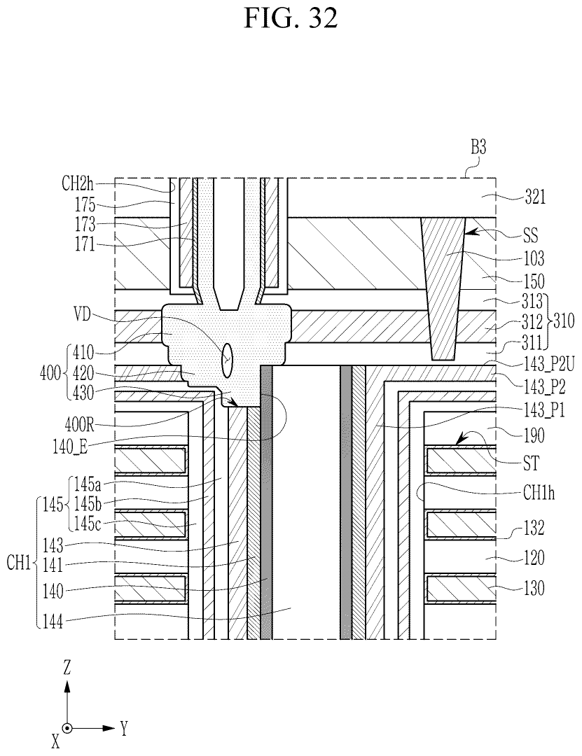

Referring to FIG. 32, the contact pad 400 may be formed in the contact pad recess 400R. Specifically, the preliminary channel layer 170P may be removed, and the contact pad 400 may be formed within the contact pad recess 400R. The contact pad 400 may be formed conformally along an inner sidewall of the contact pad recess 400R. In this case, in a process of forming the contact pad 400 conformally within the contact pad recess 400R, the void VD may be formed inside the contact pad 400. Meanwhile, in the process of forming the contact pad 400, a material layer of a contact pad 400 may be formed within the second channel hole CH2h.

Accordingly, in the semiconductor device according to an embodiment, the third portion 430 and the second portion 420 of the contact pad 400 are in contact with the exterior side 140E of the first channel layer 140, and the first portion 410 of the contact pad 400 is in contact with the upper surface of the first channel layer 140. Accordingly, a contact area between the contact pad 400 and the first channel layer 140 may be increased. Even when at least a part of the second channel structure CH2 does not overlap the first channel structure CH1 in the third direction (Z direction), a contact area between the first channel layer 140 and contact pad 400 can be secured. Therefore, reliability of the semiconductor device 100 can be secured.

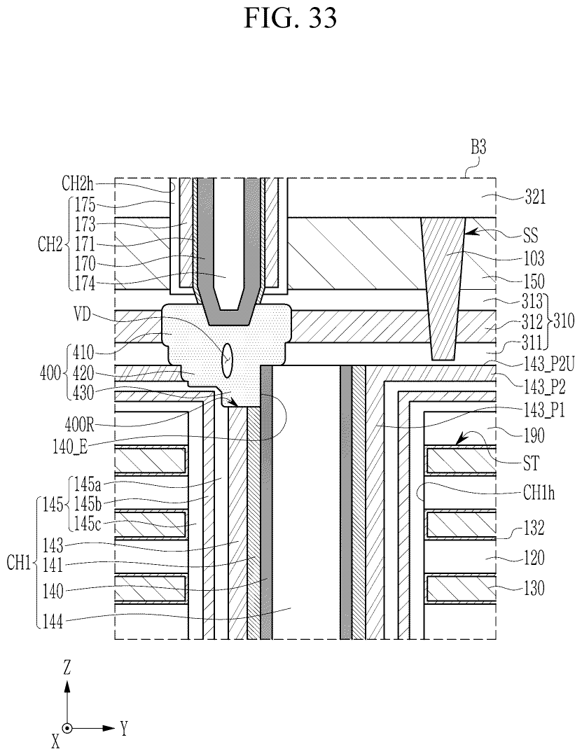

Referring to FIG. 33, the material layer of the contact pad 400 disposed within the second channel hole CH2h may be removed, and the second channel layer 170 and the second core insulation layer 174 may be formed.

Specifically, the second channel layer 170 may be conformally formed in the second channel hole CH2h. After that, the second core insulation layer 174 may be formed by filling the second channel hole CH2h with an insulating material and then performing a planarization process. In the planarization process, a part of the first upper insulation layer 321 may be removed. Accordingly, the second channel structure CH2 can be formed.

Referring to FIG. 3, a second upper insulation layer 322 covering the second channel structure CH2 may be formed. Next, a stud 181 that penetrates the second upper insulation layer 322 and is in contact with the second channel structure CH2 may be formed. Then, a third upper insulation layer 323 covering the second upper insulation layer 322, a contact plug 182 that penetrates the third upper insulation layer 323 and contacts the stud 181, and an upper wire 183 on the contact plug 182 are formed such that the semiconductor device 100 shown in FIG. 3 can be formed.

Hereinafter, an example of an electronic system including the above-described semiconductor device will be described in detail with reference to FIG. 34 to FIG. 37.

FIG. 34 illustrates an electronic system including a semiconductor device according to some embodiments.

Referring to FIG. 34, an electronic system 1000 according to some embodiments may include a semiconductor device 1100 and a controller 1200 electrically connected to the semiconductor device 1100. The electronic system 1000 may be a storage device including one or a plurality of semiconductor devices 1100 or an electronic device including a storage device. For example, the electronic system 1000 may be a solid-state drive device (SSD) device, a universal serial bus (USB), a computing system, a medical device, or a communication apparatus including one or a plurality of semiconductor devices 1100.

The semiconductor device 1100 may be a non-volatile memory device, and, for example, it may be the NADN flash memory device described with reference to FIG. 1 to FIG. 14. The semiconductor device 1100 may include a first structure 1100F and a second structure 1100S on the first structure 1100F. In some embodiments, the first structure 1100F may be disposed next to the second structure 1100S. The first structure 1100F may be a peripheral circuit structure including a decoder circuit 1110, a page buffer 1120, and a logic circuit 1130. The second structure 1100S may be a memory cell structure including a bit line BL, a common source line CSL, a word line WL, a first upper gate line UL1 and a second upper gate line UL2, a first lower gate line LL1 and a second lower gate line LL2, and a memory cell string CSTR between the bit line BL and the common source line CSL.

In the second structure 1100S, each of the memory cell strings CSTR may include lower transistors LT1 and LT2 that are adjacent to the common source line CSL, upper transistors UT1 and UT2 that are adjacent to the bit line BL, and a plurality of memory cell transistors MCT disposed between the lower transistors LT1 and LT2 and the upper transistors UT1 and UT2. The number of lower transistors LT1 and LT2 and the number of upper transistors UT1 and UT2 may vary depending on embodiments.

In some embodiments, the lower transistors LT1 and LT2 may include a ground selection transistor, and the upper transistors UT1 and UT2 may include a string selection transistor. The first lower gate line LL1 and the second lower gate line LL2 may be gate electrodes of the lower transistors LT1 and LT2, respectively. The word line WL may be a gate electrode of a memory cell transistor MCT, and the upper gate lines UL1 and UL2 may be gate electrodes of the upper transistors UT1 and UT2, respectively.

The common source line CSL, the first lower gate line LL1 and the second lower gate line LL2, the word line WL, and the first upper gate line UL1 and the second upper gate line UL2 may be electrically connected to a decoder circuit 1110 through a first connection wire 1115 extending toward the second structure 1100S in the first structure 1100F. The bit line BL may be electrically connected to the page buffer 1120 through a second connection wire 1125, which extends toward the second structure 1100S in the first structure 1100F.

In the first structure 1100F, the decoder circuit 1110 and the page buffer 1120 may perform control operations for at least one memory cell transistor selected from the plurality of memory cell transistors MCT. The decoder circuit 1110 and the page buffer 1120 may be controlled by a logic circuit 1130. The semiconductor device 1100 may communicate with a controller 1200 through an input/output pad 1101 that is electrically connected to the logic circuit 1130. The input/output pad 1101 may be electrically connected to the logic circuit 1130 through an input/output connection wire 1135 that extends toward the second structure 1100S in the first structure 1100F.

The controller 1200 may include a processor 1210, a NAND controller 1220, and a host interface 1230. Depending on embodiments, the electronic system 1000 may include a plurality of semiconductor devices 1100, and, in this case, the controller 1200 may control a plurality of semiconductor devices 1100.

The processor 1210 may control the overall operation of the electronic system 1000, including the controller 1200. The processor 1210 may operate according to predetermined firmware and may access the semiconductor device 1100 by controlling the NAND controller 1220. The NAND controller 1220 may include a NAND interface 1221 that processes communication with the semiconductor device 1100. Through the NAND interface 1221, control instructions for controlling the semiconductor device 1100, data to be written to the memory cell transistor MCT of the semiconductor device 1100, data read from the memory cell transistor MCT of the semiconductor device 1100 may be transmitted. The host interface 1230 may provide a communication function between the electronic system 1000 and an external host. When receiving control instructions from the external host through the host interface 1230, the processor 1210 may control the semiconductor device 1100 in response to the control instructions.

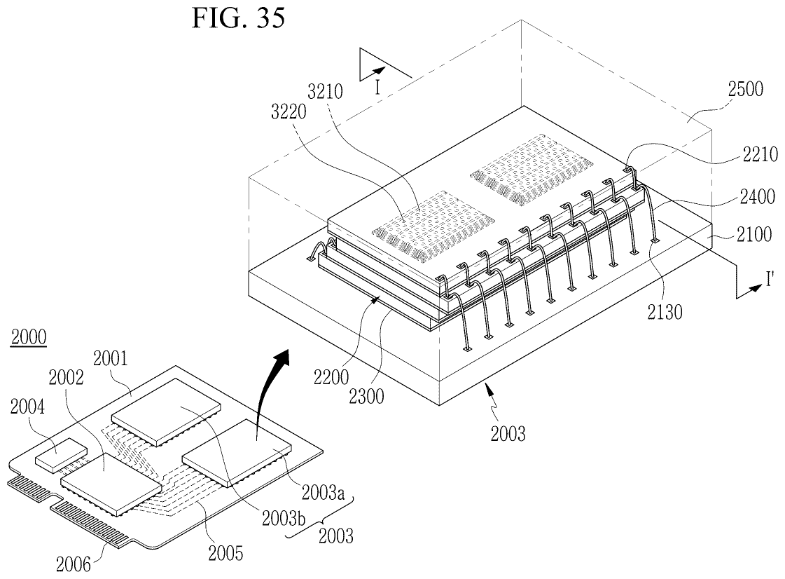

FIG. 35 is a perspective view of an electronic system including a semiconductor device according to some embodiments.

Referring to FIG. 35, an electronic system 2000 according to some embodiment may include a main substrate 2001, a controller 2002 mounted on the main substrate 2001, one or more semiconductor packages 2003, and a dynamic random access memory (DRAM) 2004. The semiconductor package 2003 and the DRAM 2004 may be connected to the controller 2002 through a wire pattern 2005 formed on the main substrate 2001.

The main substrate 2001 may include a connector 2006 that includes a plurality of pins coupled to an external host. The number and arrangement of the plurality of pins in the connector 2006 may vary depending on a communication interface between the electronic system 2000 and the external host. In some embodiments, the electronic system 2000 may communicate with the external host according to any one of interfaces such as a universal serial bus (USB), a peripheral component interconnect express (PCI-express), serial advanced technology attachment (SATA), and an M-Phy for a universal flash storage (UFS). In some embodiments, the electronic system 2000 may operate with power supplied from the external host through the connector 2006. The electronic system 2000 may further include a power management integrated circuit (PMIC) that distributes power supplied from the external host to the controller 2002 and the semiconductor package 2003.

The controller 2002 may record data in a semiconductor package 2003 or read data from the semiconductor package 2003, and may improve the operation speed of the electronic system 2000.

The DRAM 2004 may be a buffer memory to alleviate a speed difference between the semiconductor package 2003, the data storage space, and the external host. The DRAM 2004 included in the electronic system 2000 may also operate as a type of cache memory and provide a space to temporarily store data during control operations for the semiconductor package 2003. When the electronic system 2000 includes the DRAM 2004, the controller 2002 may further include a DRAM controller for controlling the DRAM 2004 in addition to a NAND controller for controlling the semiconductor package 2003.

The semiconductor package 2003 may include first and second semiconductor packages 2003a and 2003b spaced apart from each other. The first and second semiconductor packages 2003a and 2003b may be semiconductor packages each including a plurality of semiconductor chips 2200. Each of the first and second semiconductor packages 2003a and 2003b may include a package substrate 2100, a semiconductor chip 2200 disposed on the package substrate 2100, an adhesive layer 2300 disposed on a bottom surface of each semiconductor chip 2200, a connection structure 2400 electrically connecting the semiconductor chip 2200 to the package substrate 2100, and a molding layer 2500 covering the semiconductor chip 2200 and the connection structure 2400 on the package substrate 2100.

The package substrate 2100 may be a printed circuit board including an upper package pad 2130. Each semiconductor chip 2200 may include an input/output pad 2210. The input/output pad 2210 may correspond to the input/output pad 1101 of FIG. 34. Each semiconductor chip 2200 may include a gate stacking structure 3210 and a channel structure 3220. The semiconductor chip 2200 may include the semiconductor device described with reference to FIG. 1 to FIG. 14.

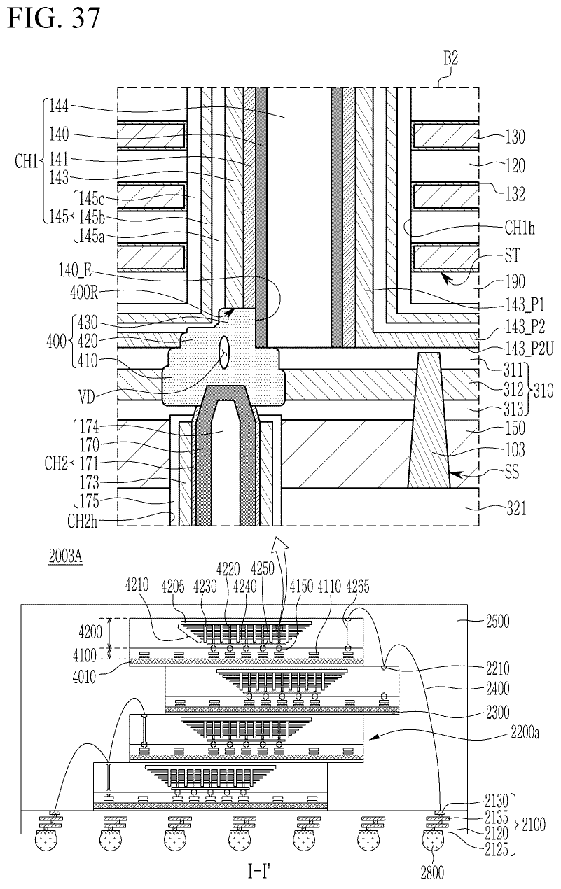

FIG. 36 and FIG. 37 are cross-sectional views of a semiconductor package according to some embodiments.

Referring to FIG. 36, in a semiconductor package 2003, a package substrate 2100 may be a printed circuit board. The package substrate 2100 may include a package substrate body portion 2120, an upper package pad 2130 disposed on an upper surface of the package substrate body portion 2120, a lower package pad 2125 disposed on a bottom surface of the package substrate body portion 2120 or exposed through the bottom surface of the package substrate body portion 2120, and an inner wire 2135 electrically connecting the upper package pad 2130 to the lower package pad 2125 in the package substrate body portion 2120. The upper package pad 2130 may be electrically connected to the connection structure 2400. The lower package pad 2125 may be connected to a wiring pattern 2005 of a main substrate 2010 of an electronic system 2000 through a conductive connection portion 2800 as shown in FIG. 35.

The semiconductor chip 2200 may include a semiconductor substrate 3010 and a first structure 3100 and a second structure 3200 that are sequentially stacked on the semiconductor substrate 3010. The first structure 3100 may include a peripheral circuit region including a peripheral wire 3110. The second structure 3200 may include a common source line 3205, a gate stacking structure 3210 disposed on the common source line 3205, a channel structure 3220 and a separation structure 3230 penetrating the gate stacking structure 3210, a bit line 3240 electrically connected to the channel structure 3220, and a gate connection wire electrically connected to a word line WL (refer to FIG. 34) of the gate stacking structure 3210.

In the semiconductor chip 2200 according to an embodiment, a contact area between the contact pad 400 and the first channel structure CH1 increases, and accordingly the first channel structure CH1 and the second channel structure CH2 can be stably connected with each other.

Each of the semiconductor chips 2200 may include a through wire 3245 that is electrically connected to the peripheral wire 3110 of the first structure 3100 and extends into the second structure 3200. The through wire 3245 may penetrate the gate stacking structure 3210, and may be further disposed at an outer side of the gate stacking structure 3210. Each of the semiconductor chips 2200 may further include an input/output connection pad 3265 electrically connected to the peripheral wire 3110 of the first structure 3100 and extending into the second structure 3200 and an input/output pad 2210 electrically connected to the input/output connection wire 4265.

In the semiconductor package 2003 according to some embodiments, the plurality of semiconductor chips 2200 may be electrically connected with each other by a connection structure 2400 in the form of a bonding wire. In some embodiments, the plurality of semiconductor chips 2200 or the plurality of portions constituting the semiconductor chip may be electrically connected with each other by a connection structure including a through electrode (through silicon via, TSV).

Referring to FIG. 37, in a semiconductor package 2003A, each of the semiconductor chips 2200a may include a semiconductor substrate 4010, a first structure 4100 disposed on the semiconductor substrate 4010, and a second structure 4200 bonded with the first structure 4100 by wafer bonding and disposed on the first structure 4100.

The first structure 4100 may include a peripheral circuit region including a peripheral wire 4110 and a first bonding structure 4150. The second structure 4200 may include a common source line 4205, a gate stacking structure 4210 disposed between the common source line 4205 and the first structure 4100, a channel structure 4220 and a separation structure 4230 penetrating the gate stacking structure 4210, and a second bonding structure 4250 electrically connected to the channel structure 4220 and a word line WL (refer to FIG. 34) of gate stacking structure 4210. For example, the second bonding structure 4250 may be electrically connected to the channel structure 4220 and the word line WL through a bit line 3240 electrically connected to the channel structure 4220 and a gate connection wire electrically connected to the word line WL, respectively. The first bonding structure 4150 of the first structure 4100 and the second bonding structure 4250 of the second structure 4200 may be bonded with each other while being in contact with each other. A bonded portion of the first bonding structure 4150 and the second bonding structure 4250 may be formed of, for example, copper (Cu).

In the semiconductor chip 2200a according to the embodiment, a contact area between the contact pad 400 and the first channel structure CH1 increases, and thus the first channel structure CH1 and the second channel structure CH2 can be stably connected with each other.

Each of the semiconductor chips 2200a may further include an input/output pad 2210 and an input/output connection wire 4265 below the input/output pad 2210. The input/output connection wire 4265 may be electrically connected to a part of the second bonding structure 4250.

In an embodiment, the plurality of semiconductor chips 2200 of the semiconductor package 2003 may be electrically connected with each other by the connection structure 2400 formed in the shape of a bonding wire. In some embodiments, the plurality of semiconductor chips 2200 or a plurality of portions constituting the semiconductor chip may be electrically connected with each other by a connection structure including a through electrode.

Although an embodiment has been described in detail above, the scope of the present invention is not limited thereto, and various modifications of a person of ordinary skill in the art using the basic concept of the present invention defined in the following claims range and Improved forms also fall within the scope of the present invention.

### DESCRIPTION OF SYMBOLS

100: semiconductor device
130: plurality of gate electrode
CH1: first channel structure
150: second selection gate electrode
CH2: second channel structure
400: contact pad
410: first portion
420: second portion
430: third portion
310: insulation pattern

What is claimed is:

1. A semiconductor device comprising:
a substrate;
a stacking structure disposed on the substrate and including a plurality of gate electrodes that are stacked on each other in a vertical direction and are spaced apart from each other, wherein the vertical direction is perpendicular to an upper surface of the substrate;
a first channel structure penetrating the plurality of gate electrodes and including a first channel layer extending lengthwise in the vertical direction and a first ferroelectric layer including a vertical portion disposed between the first channel layer and a side surface of the stacking structure and a horizontal portion disposed on an upper surface of the stacking structure;
an insulation pattern disposed on the upper surface of the stacking structure;
a contact pad that penetrates the insulation pattern and is connected to the first channel structure;
a selection gate electrode disposed on the insulation pattern; and
a second channel structure that penetrates the selection gate electrode, is connected to the contact pad, and extends lengthwise in the vertical direction,
wherein the contact pad is disposed in a space between the second channel structure and the first channel structure, and
wherein the contact pad comprises:
a first portion that penetrates the insulation pattern and contacts an upper surface of the first channel layer;
a second portion that penetrates the horizontal portion of the first ferroelectric layer and contacts an exterior surface of the first channel layer; and
a third portion that protrudes from a bottom surface of the second portion and contacts the exterior surface of the first channel layer.

2. The semiconductor device of claim 1,
wherein the third portion is disposed on the vertical portion of the first ferroelectric layer.

3. The semiconductor device of claim 2,
wherein at least a part of the first portion is disposed on an upper surface of the horizontal portion of the first ferroelectric layer.

4. The semiconductor device of claim 1,
wherein the insulation pattern comprises:
a first insulation pattern that is disposed on the horizontal portion of the first ferroelectric layer;
a second insulation pattern that is disposed on the first insulation pattern; and
a third insulation pattern that is disposed on the second insulation pattern, and
wherein the second insulation pattern includes a material having etch selectivity with respect to the first insulation pattern and the third insulation pattern.

5. The semiconductor device of claim 1,
wherein a width, in a first horizontal direction, of the first portion is greater than a width, in the first horizontal direction, of the third portion, and
wherein the first horizontal direction is parallel to the upper surface of the substrate.

6. The semiconductor device of claim 5,
wherein the width, in the first horizontal direction, of the third portion is greater than a width, in the first horizontal direction, of the vertical portion of the first ferroelectric layer.

7. The semiconductor device of claim 1,
wherein at least a part of the first channel structure overlaps the second channel structure in the vertical direction.

8. The semiconductor device of claim 7,
wherein at least a part of the second portion does not overlap the third portion in the vertical direction.

9. The semiconductor device of claim 1,
wherein the contact pad further comprises a fourth portion that is protruded from a bottom surface of the third portion, and that is disposed between the vertical portion of the first ferroelectric layer and the side surface of the first channel layer.

10. The semiconductor device of claim 1,
wherein the contact pad further comprises a fifth portion protruded from a bottom surface of the first portion and contacting an interior surface of the first channel layer.

11. The semiconductor device of claim 1, wherein:
the first channel structure comprises a first insulation layer surrounding the vertical portion of the first ferroelectric layer, and
at least a part of the third portion overlaps the first insulation layer in the vertical direction.

12. The semiconductor device of claim 11,
wherein the first insulation layer is further disposed between the horizontal portion of the ferroelectric layer and the upper surface of the stacking structure.

13. The semiconductor device of claim 11,
wherein the first insulation layer comprises:
a first blocking layer surrounding the vertical portion of the first ferroelectric layer;
a charge inflow layer surrounding the first blocking layer; and
a second blocking layer disposed between the charge inflow layer and the stacking structure.

14. The semiconductor device of claim 1,
wherein the contact pad comprises polysilicon doped with an N-type impurity.

15. A semiconductor device comprising:
a substrate;
a stacking structure disposed on the substrate and including a plurality of gate electrodes that are stacked on each other and are spaced apart from each other;
a first channel structure that penetrates the plurality of gate electrodes of the stacking structure, and includes a first channel layer extending in a vertical direction perpendicular to an upper surface of the substrate, a first ferroelectric layer including a vertical portion disposed between the first channel layer and a side surface of the stacking structure and a horizontal portion disposed on an upper surface of the stacking structure, and a first insulation layer disposed between the first ferroelectric layer and the stacking structure;
an insulation pattern disposed on the upper surface of the stacking structure;
a contact pad that penetrates the insulation pattern and is connected to the first channel structure;
a selection gate electrode disposed on the insulation pattern; and
a second channel structure that penetrates the selection gate electrode and is connected to the contact pad,
wherein the second channel structure includes a second channel layer extending in the vertical direction and a second ferroelectric layer disposed between the second channel layer and the selection gate electrode, and
wherein the contact pad comprises:
a first portion penetrating the insulation pattern,
a second portion penetrating the horizontal portion of the first ferroelectric layer, and
a third portion protruded from a bottom surface of the second portion and contacting an exterior surface of the first channel layer.

16. The semiconductor device of claim 15,
wherein the third portion is disposed on the vertical portion of the first ferroelectric layer.

17. The semiconductor device of claim 16,
wherein at least a part of the third portion overlaps the first insulation layer in the vertical direction.

18. The semiconductor device of claim 15,
wherein the second portion overlaps the first insulation layer in a horizontal direction parallel to the upper surface of the substrate.

19. The semiconductor device of claim 15,
wherein the contact pad includes the same material as the second channel layer.

20. An electronic system comprising:
a first substrate;
a semiconductor device disposed on the first substrate; and
a controller that is disposed on the first substrate and electrically connected to the semiconductor device,
wherein the semiconductor device comprises:
a peripheral circuit region;
a cell region that includes an input/output connection wire electrically connected to the peripheral circuit region; and
an input/output pad that is electrically connected to the input/output connection wire extending into the cell region,
wherein the cell region comprises:
a second substrate;
a stacking structure disposed on the second substrate and including a plurality of gate electrodes that are stacked on each other and are spaced apart from each other;
a first channel structure that penetrates the plurality of gate electrodes of the stacking structure, and includes a first channel layer extending in a vertical direction perpendicular to an upper surface of the second substrate and a first ferroelectric layer including a vertical portion disposed between the first channel layer and a side surface of the stacking structure and a horizontal portion disposed on an upper surface of the stacking structure;
an insulation pattern disposed on the upper surface of the stacking structure;
a contact pad that penetrates the insulation pattern and is connected to the first channel structure;
a selection gate electrode disposed on the insulation pattern; and
a second channel structure that penetrates the selection gate electrode and contacts the contact pad, and extends in the vertical direction, and
wherein the contact pad comprises:
a first portion that penetrates the insulation pattern and contacts an upper surface of the first channel layer;
a second portion that penetrates the horizontal portion of the first ferroelectric layer and contacts an exterior surface of the first channel layer; and
a third portion that is protruded from a bottom surface of the second portion and contacts the exterior surface of the first channel layer.
